(19) United States
(12) Patent Application Publication
(10) Pub. No.: US 2024/0422921 A1
(43) Pub. Date: Dec. 19, 2024

(54) Electronic Device Enclosures

(71) Applicant: DISH Network L.L.C., Englewood, CO (US)

(72) Inventors: Steven Allen Nedved, Littleton, CO (US); William Roberts, Centennial, CO (US); Andrew David McAuley, Lone Tree, CO (US); Jerome A. LaPalme, Aurora, CO (US); Svitlana Trygubova, Lakewood, CO (US); Roy Gonzales, Englewood, CO (US)

(73) Assignee: DISH Network L.L.C., Englewood, CO (US)

(21) Appl. No.: 18/211,347

(22) Filed: Jun. 19, 2023

(51) Int. Cl. H05K 5/00; H05K 5/02

(52) U.S. Cl. CPC H05K 5/0013; H05K 5/0208; H05K 5/0217

(57) ABSTRACT

Various electronic device enclosures, methods for securing an enclosure and methods for unsecuring an enclosure are described. An enclosure includes a first panel assembly, a second panel assembly, a plurality of first fasteners, and a plurality of second fasteners. A first fastener is provided with one of the first panel assembly and the second panel assembly. A second fastener corresponds to and is couplable with the first fastener and is provided with another of the first panel assembly and the second panel assembly. An interior location for the first fastener and/or the second fastener is not readily apparent when the enclosure is in a secured configuration. Coupling the first fastener with the second fastener secures the enclosure. The enclosure may be a cover flex window enclosure, a cover flex clip enclosure, a cover slide & hook clip enclosure, or a hinged cover with flex clip enclosure.

### TECHNICAL FIELD

The technology described herein generally relates to enclosures for set-top boxes and other forms of electronic devices.

### BACKGROUND

Electronic devices commonly include an enclosure that provides a separation between one or more interior compartments (individually and collectively forming an internal environment) and an exterior environment. An electronic device enclosure may have any form, shape, or configuration and are commonly formed in the shapes of a rectangle, square, cube, polygon, or similar configuration. An enclosure commonly provides a separation of internal components from external substances such as water, dust, heat, or the like. The enclosure also commonly provides a physical hardness and robustness to the electronic device that enables the electronic device's interior components (e.g., printed circuit boards, integrated circuits, and the like) to withstand a given level of protection, in the event of a fall or impact with another object, where such an impact (absent the enclosure) might jeopardize, degrade the integrity and/or operations of the electronic device and/or components therein.

An enclosure typically includes various sides and/or panels (herein, each being a “panel”) that are fastened together.

Yet, components of an electronic device occasionally fail, or the internal environment otherwise need to be accessed Current methods used to secure panels to each other during manufacturing often present obstacles to technicians and/or others when release of a panel, relative to another panel, to gain access to the interior of the electronic device is needed. Such obstacles often increase an amount of time needed to separate the one or more panels from each other and often require technicians with specialized skills and/or knowledge. Accordingly, enclosures which have two or more panels that can be easily secured and released and resecured for a later use are needed. Methods and tools for securing and releasing panels are needed. The various implementations of the present disclosure address these and other needs.

### SUMMARY

Various implementations are described of enclosures for set-top boxes.

For at least one implementation, an electronic device enclosure may include a first panel assembly; a second panel assembly; a plurality of first fasteners; and a plurality of second fasteners. The first fastener of the plurality of first fasteners may be provided with one of the first panel assembly and the second panel assembly. A second fastener of the plurality of second fasteners corresponds to the first fastener and may be provided with another of the first panel assembly and the second panel assembly. The first fastener is couplable with the second fastener. A location inside the electronic device enclosure for at least one of the first fastener and the second fastener is not readily apparent to a non-skilled technician when the electronic device enclosure is in a secured configuration. A coupling of the first fastener with the second fastener results in the electronic device enclosure having a secured configuration.

For at least one implementation, an electronic device enclosure may be a cover flex window (“CFW”) enclosure. The first fastener may be a CFW clip stop assembly and the second fastener may be a CFW clip assembly. The CFW clip assembly may include a CFW clip bottom portion formed on a bottom panel of the second panel assembly, a CFW clip top portion formed with the CFW clip bottom portion, and a CFW clip ridge formed as a part of the CFW clip top portion. The CFW clip top portion may extend horizontally relative to the bottom panel of the second panel assembly and above the CFW clip bottom portion.

For at least one implementation of a CFW enclosure, a CFW clip stop assembly may include a CFW clip stop ridge, that is horizontal with a top panel of the first panel assembly, and a CFW clip stop wall formed with and perpendicular to the CFW clip stop ridge. The CFW clip ridge couples with the CFW clip stop ridge when the first panel assembly is coupled with the second panel assembly.

For at least one implementation of a CFW enclosure, an electronic device enclosure may further include a first CFW window, a second CFW window, a second-first fastener of the plurality of first fasteners, and a second-second fastener of the plurality of second fasteners. The first fastener may be provided with the bottom panel for the second panel assembly. The second-first fastener may be provided with the bottom panel for the second panel assembly. The second fastener may be provided with a first side panel for the first panel assembly and the second-second fastener may be provided with a second side panel for the first panel assembly. The first CFW window corresponds with a first location on the first side panel for the first panel assembly. The second CFW window corresponds with a second location on the second side panel for the first panel assembly. The first location and the second location are opposingly aligned.

For at least one implementation of a CFW enclosure, when the electronic device enclosure is in the secured configuration, the second-first fastener is coupled with the second-second fastener. The first CFW window facilitates application of a first force on the first fastener when coupled to the second fastener. The second CFW window facilitates application of a second force on the second-first fastener when coupled to the second-second fastener.

For at least one implementation of a CFW enclosure, an application of a first force in conjunction with the application of a second force releases the first fastener from the second fastener, releases the second-first fastener from the second-second fastener, and the first panel assembly is unsecured from the second panel assembly. For at least one implementation of a CFW enclosure, when the first fastener is coupled with the second fastener, the CFW clip bottom portion couples with the CFW clip stop wall to form a rigid combined structure which increases structural rigidity of the electronic device enclosure.

For at least one implementation, an electronic device enclosure may be a cover flex clip (“CFC”) enclosure. For a CFC enclosure, the first fastener may be a CFC clip assembly and the second fastener may be a CFC hook assembly. The CFC clip assembly may include a CFC clip bottom portion formed on an interior portion of a bottom panel of the second panel assembly and a CFC clip top portion formed with the CFC clip bottom portion. The CFC clip top portion extends horizontally relative to the bottom panel of the second panel assembly and above the CFC clip bottom portion.

For at least one implementation of a CFC enclosure, a CFC clip ridge is formed as a part of the CFC clip top portion. The CFC hook assembly may include a CFC hook opening and a CFW hook bottom portion, located below the CFC hook opening. The CFC hook opening is couplable with the CFC clip ridge when the first panel assembly is coupled with the second panel assembly.

For at least one implementation of a CFC enclosure, a CFC clip access slot is formed in the bottom panel. The CFC clip access slot facilitates access by a tool prong, located below the bottom panel of the electronic device enclosure, into an internal environment formed by a secured electronic device in order to facilitate a release of the CFC clip ridge from the CFC hook opening. Upon releasing of CFC clip ridges for the plurality of first fasteners from corresponding CFC hook openings for the plurality of second fasteners, the first panel assembly is released from the second panel assembly and the electronic device enclosure obtains an unsecured configuration.

For at least one implementation, a CFC enclosure may further include at least one second-first fastener of the plurality of first fasteners, and at least one second-second fastener of the plurality of second fasteners. The at least one second-first fastener may be formed on an interior surface of a top panel of the first panel assembly. The at least one second-second fastener may be formed on an interior surface of a back panel of the second panel assembly. The at least one second-first fastener is couplable with the at least one second-second fastener. For at least one implementation of a CFC enclosure, the at least one second-first fastener is a CFC clip assembly and the at least one second-second fastener is a CFC access and retention slot.

For at least one implementation of a CFC enclosure, the CFC clip assembly may include a CFC clip bottom portion formed on the interior surface of the top panel, a CFC clip top portion formed with the CFC clip bottom portion, and a CFC clip ridge formed as a part of the CFC clip top portion. The CFC clip top portion extends horizontally downwards relative to the CFC clip bottom portion. The CFC access and retention slot comprises an opening for receiving and retaining the CFC clip ridge when the first panel assembly is mated to the second panel assembly. The CFC access and retention slot can receive a prong of a tool which when inserted therein facilitates dislocation of the CFC clip ridge from the CFC access and retention slot. Upon releasing of CFC clip ridges for the at least one second-first fasteners from corresponding CFC access and retention slots for the second-second fasteners and releasing of any first fastener from any corresponding second fasteners, the first panel assembly is released from the second panel assembly and the electronic device enclosure obtains an unsecured configuration.

For at least one implementation, an electronic device enclosure may be a cover slide & hook clip (“CSHC”) enclosure. For at least one implementation of a CSHC enclosure, the first fastener may be one or more CSHC prong holes and the second fastener may be one or more CSHC prongs. The one or more CSHC prongs are couplable with a respectively corresponding CSHC prong hole from the one or more CSHC prong holes. The electronic device enclosure is in a secured configuration when the one or more CSHC prongs are respectively coupled with the respectively corresponding CSHC prong hole.

For at least one implementation of a CSHC enclosure, the first fastener is one or more CSHC hook assemblies and the second fastener is one or more CSHC hook cavity assemblies. The one or more CSHC hook assemblies are couplable with a respectively corresponding CSHC hook cavity assembly from the one or more CSHC hook cavity assemblies. The electronic device enclosure is in a secured configuration when the one or more CSHC hook assemblies are respectively coupled with the respectively corresponding CSHC hook cavity assembly.

For at least one implementation of a CSHC enclosure may include a second-first fastener and a second-second fastener. For at least one implementation of a CSHC enclosure, the second-first fastener may be one or more CSHC prong holes and the second-second fastener may be one or more CSHC prongs. The one or more CSHC prongs are couplable with a respectively corresponding CSHC prong hole from the one or more CSHC prong holes. The electronic device enclosure is in a secured configuration when the one or more CSHC prongs are coupled with a respectively corresponding CSHC prong hole and the one or more CSHC hook assemblies are coupled with the respectively corresponding CSHC hook cavity assembly.

For at least one implementation, an electronic device enclosure may be a hinged cover with flex clip (“HCFC”) enclosure. For at least one implementation of an HCFC enclosure, the first fastener may be one or more HCFC hinges and the second fastener may be one or more HCFC hinge clips. The one or more HCFC hinges are couplable with a respectively corresponding HCFC hinge clip. The electronic device enclosure is configured into a secured configuration when the one or more HCFC hinges are coupled with the respectively corresponding one or more HCFC hinge clips.

For at least one implementation, an HCFC enclosure may include a second-first fastener and a second-second fastener. The second-first fastener may be one or more HCFC clip assemblies and the second-second fastener may be one or more HCFC hooks. The one or more HCFC clip assemblies are couplable with a respectively corresponding HCFC hook from the one or more HCFC hooks. The electronic device enclosure is in a secured configuration when the one or more HCFC clip assemblies are coupled with a respectively corresponding HCFC hook.

For at least one implementation, an HCFC enclosure may include a first HCFC panel assembly. The first HCFC panel assembly may include an HCFC top panel, an HCFC first side panel, an HCFC second side panel, and an HCFC front panel. The second HCFC panel assembly may include an HCFC back panel and an HCFC bottom panel. The one or more HCFC hinges may be provided on the HCFC back panel. The one more HCFC hinge clips may be provided on the HCFC top panel. The one or more HCFC clip assemblies may be provided on the HCFC bottom panel. The one or more HCFC hooks may be provided on at least one of the HCFC top panel, the HCFC first side panel, the HCFC front panel, and the HCFC second side panel.

### BRIEF DESCRIPTION OF THE DRAWINGS

The features, aspects, advantages, functions, modules, and components of the devices, systems and processes provided by the various implementations of implementations of the present disclosure are further disclosed herein regarding at least one of the following descriptions and accompanying drawing figures. In the appended figures, similar components or elements of the same type may have the same reference number and may include an additional alphabetic designator, such as 108a-108n, and the like, wherein the alphabetic designator indicates that the components bearing the same reference number, e.g., 108, share common properties and/or characteristics. Further, various views of a component may be distinguished by a first reference label followed by a dash and a second reference label, wherein the second reference label is used for purposes of this description to designate a view of the component. When the first reference label is used in the specification, the description is applicable to any of the similar components and/or views having the same first reference number irrespective of any additional alphabetic designators or second reference labels, if any.

FIG. 1A is an isometric view of a first enclosure, and in accordance with at least one first implementation of the present disclosure.

FIG. 1B is an exploded view of the first enclosure of FIG. 1A wherein a first assembly of a top panel, 1^{st} side panel, and 2^{nd} side panel have been separated from and raised above a second assembly of a bottom panel and rear panel for the first enclosure of FIG. 1A, and in accordance with the at least one first implementation of the present disclosure.

FIG. 1C is a first sectional view of the first assembly and second assembly of the first enclosure of FIG. 1A, as separated in accordance with the exploded view of FIG. 1, taken along a 1C-1C sectional line shown in FIG. 1A, and in accordance with the at least one first implementation of the present disclosure.

FIG. 1D is a second sectional view of the first assembly and the second assembly of the first enclosure of FIG. 1A, as separated in accordance with the exploded view of FIG. 1B, taken along a 1D-1D sectional line shown in FIG. 1C, and in accordance with the at least one first implementation of the present disclosure.

FIG. 1E is a third sectional view of the first assembly and the second assembly of the first enclosure of FIG. 1A, as separated in accordance with the exploded view of FIG. 1D, taken along a 1E-1E sectional line shown in FIG. 1A, and in accordance with the at least one first implementation of the present disclosure.

FIG. 2A is an isometric view of a second enclosure, and in accordance with at least one second implementation of the present disclosure.

FIG. 2B is an exploded view of the second enclosure of FIG. 2A wherein a first assembly of a top panel, 1^{st} side panel, and 2^{nd} side panel have been separated from raised above a second assembly of a bottom panel and rear panel for the second enclosure of FIG. 2A, and in accordance with the at least one second implementation of the present disclosure.

FIG. 2C is a first sectional view of the first assembly and second assembly of the second enclosure of FIG. 2A, as separated in accordance with the exploded view of FIG. 2B, taken along a 2C/D-2C/D sectional line shown in FIG. 2A, and in accordance with the at least one second implementation of the present disclosure.

FIG. 2D is a second sectional view of the first assembly and the second assembly of the second enclosure of FIG. 2A, as separated in accordance with the exploded view of FIG. 2B and taken along the 2C/D-2C/D sectional line shown in FIG. 2A, and in accordance with the at least one second implementation of the present disclosure.

FIG. 3A is an isometric view of a third enclosure, and in accordance with at least one third implementation of the present disclosure.

FIG. 3B is an exploded view of the third enclosure of FIG. 3A wherein a first assembly of a top panel, 1^{st} side panel, and 2^{nd} side panel have been separated from raised above a second assembly of a bottom panel and rear panel for the third enclosure of FIG. 3A, and in accordance with the at least one third implementation of the present disclosure.

FIG. 3C is a first sectional view of the first assembly and second assembly of the third enclosure of FIG. 3A, as separated in accordance with the exploded view of FIG. 3B, taken along a 3C-3C sectional line shown in FIG. 3A, and in accordance with the at least one third implementation of the present disclosure.

FIG. 3D is a second sectional view of the first assembly and the second assembly of the third enclosure of FIG. 3A, as separated in accordance with the exploded view of FIG. 3B, taken along the 3D/3E-3D/3E sectional line shown in FIG. 3A, and in accordance with the at least one third implementation of the present disclosure.

FIG. 3E is a third sectional view of the first assembly and the second assembly of the third enclosure of FIG. 3A, as separated in accordance with the exploded view of FIG. 3B, taken along the 3D/3E-3D/3E sectional line shown in FIG. 3A, and in accordance with the at least one third implementation of the present disclosure.

FIG. 4A is an isometric view of a fourth enclosure, and in accordance with at least one fourth implementation of the present disclosure.

FIG. 4B is an exploded view of the fourth enclosure of FIG. 4A wherein a first assembly of a top panel, 1^{st} side panel, and 2^{nd} side panel have been separated from raised above a second assembly of a bottom panel and rear panel for the fourth enclosure of FIG. 4A, and in accordance with the at least one fourth implementation of the present disclosure.

FIG. 4C is a first sectional view of the first assembly and second assembly of the fourth enclosure of FIG. 4A, as separated in accordance with the exploded view of FIG. 4B, taken along a 4C-4C sectional line shown in FIG. 4A, and in accordance with the at least one fourth implementation of the present disclosure.

FIG. 4D is a second sectional view of the first assembly and the second assembly of the fourth enclosure of FIG. 4A, as separated in accordance with the exploded view of FIG. 4B, taken along the 4D-4D sectional line shown in FIG. 4A, and in accordance with the at least one fourth implementation of the present disclosure.

### DETAILED DESCRIPTION

The various implementations of the present disclosure described herein provide enclosures for which a first panel assembly for a given enclosure can be readily released from a second panels assembly for the given enclosure. It is to be appreciated that a work stand may be configured to facilitate the ready release of the first panel assembly from the second panel assembly.

As described above an enclosure typically includes two or more panel, with non-limiting examples of such panels including, for at least one implementation of the present disclosure, a top panel, bottom panel, front panel, back panel, first side panel and a second side panel (with other panels being used for non-rectangular and/or non-square configurations). The panels may be provided individually or in combination. As used herein, “panel assembly and panel assemblies” refer to both individual panels and combinations of panels that coupled or formed together to form an integrated whole. As used herein, a “panel assembly” refers to both individual panels and combinations of panels that coupled or formed together to form an integrated whole. Panel assemblies may be secured using various forms of “fasteners” with non-limiting examples including clips, hooks, pins, or the like.

One or more panel assemblies for a given enclosure may include ports via which the internal electronic components may be coupled to external devices, networks, power sources, or otherwise. The ports may include type of wired and/or wireless interface ports with non-limiting examples including power ports, Ethernet ports, Universal Serial Bus (USB) ports, video ports (such as HDMI and DISPLAYPORT ports), antenna ports, cabling ports, and others. Such ports are well known in the art and an enclosure may include any such known and/or later arising ports.

One or more of the panel assemblies may include one or more user interface components, such as video interfaces (e.g., light emitting diodes, display panels, or the like), audio interfaces (e.g., speakers, headphone ports (which may include wireless and/or wireless ports), microphones and microphone ports, or the like), tactile interfaces (e.g., touch panels, buttons, keypads, or the like), and/or other forms of human to device interfaces—any of which may be used for an enclosure.

A panel assembly used for a given enclosure may be formed using any known or later arising materials using known and/or later arising techniques for manufacturing and forming such one or more panels and panel assemblies. Non-limiting examples of panel materials may include molded plastics, shaped metals, natural products (such as wood, bamboo, or the like), other materials, and combinations thereof. Commonly at least two of the panels of an enclosure are formed so as to permit insertion of electronic components into the enclosure during manufacturing and then coupling with each other to secure the components within the interior environment relative to an external environment. The external environment may be any environment. The panels and coupling thereof may be configured in view of one or more characteristics of the external environment, with non-limiting examples of external environment characteristics including a presence or absence of moisture, dust, electromagnetic signals, atmospheric pressure, water pressure (e.g., for a water submersible enclosure), temperature, or otherwise.

For at least one implementation, an enclosure may include two or more first panel assemblies configured for “ready release” from two or more second panel assemblies—the ready release facilitating opening of the enclosure so as permit access to the internal environment and one or more components located within the enclosure.

As used herein, a “ready release” of a first panel assembly from a second panel assembly, for a given enclosure, is herein defined to occur upon the coupling of the given enclosure with one or more “enclosure opening tool(s)” to one or more fasteners. An enclosure opening tool may be generic for use with multiple types of enclosures, limited for use to a set of enclosures, and/or specifically configured for use with a given enclosure. An enclosure opening tool may be configured to apply one or more opening forces upon one or more fasteners used for a given enclosure.

A fastener may join and/or secure two or more panel assemblies together. Multiple enclosure opening tools may be used for a given enclosure where multiple panel assemblies are secured using multiple fasteners and/or multiple types of fasteners. The fasteners may be accessible along two or more planes, such as fasteners accessible by an enclosure opening tool positioned coincident with a bottom panel of a given enclosure, and a second fasteners accessible by an enclosure opening tool positioned coincident with a side panel, such as a back panel for the given enclosure.

It is to be appreciated that the enclosure opening tool(s) utilized to perform a ready release of one or more fasteners securing an enclosure may utilize, when so applied to open a given enclosure, a given quantity of force in one or more directions and/or orientations relative to one more panel assemblies for a given enclosure. The force may be applied by a human operator, an automated tool, or otherwise. The force may be applied with respect to any orientation relative to a panel assembly, such as a force applied perpendicular to the bottom plane formed by a bottom panel for a given enclosure.

For a non-limiting example, a lateral force (e.g., in a direction from a first side panel assembly towards a second side panel assembly), a perpendicular force (e.g., a force applied in a downwards direction onto a top panel assembly and towards a bottom panel assembly of an enclosure), a combination of a lateral forces and perpendicular forces, and/or other forces may be applied to an enclosure to facilitate separation of one or more first panel assemblies from one or more second panel assemblies. For at least one implementation, a force applied upon one or more panel assemblies, for a given enclosure, which facilitates release of a first panel assembly relative to and/or from a second panel assembly may be a force between 2.71 and 8.13 Newton meters.

For at least one implementation, an enclosure opening tool may be provided on and/or with a work stand that may be further configured to facilitate a lifting, lateral movement, rotational movement, or other relocations of a first panel assembly relative to a second panel assembly for a given enclosure. Upon one or more fasteners being released, access to the internal environment for a given enclosure may be facilitated by relocation of one or more first panel assemblies relative to one or more second panel assemblies. Such relocation may occur using human force, automated tools, combinations of the foregoing, or otherwise.

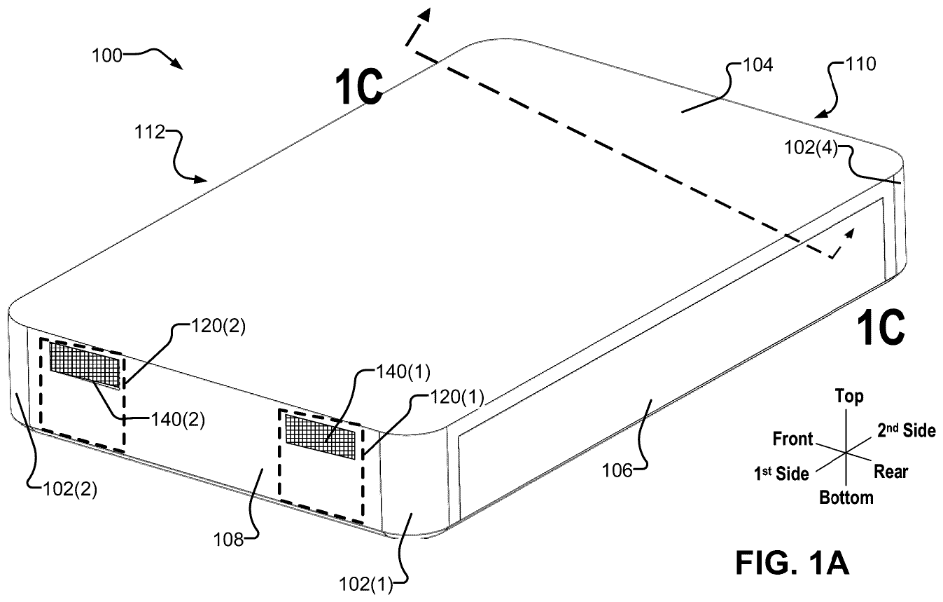

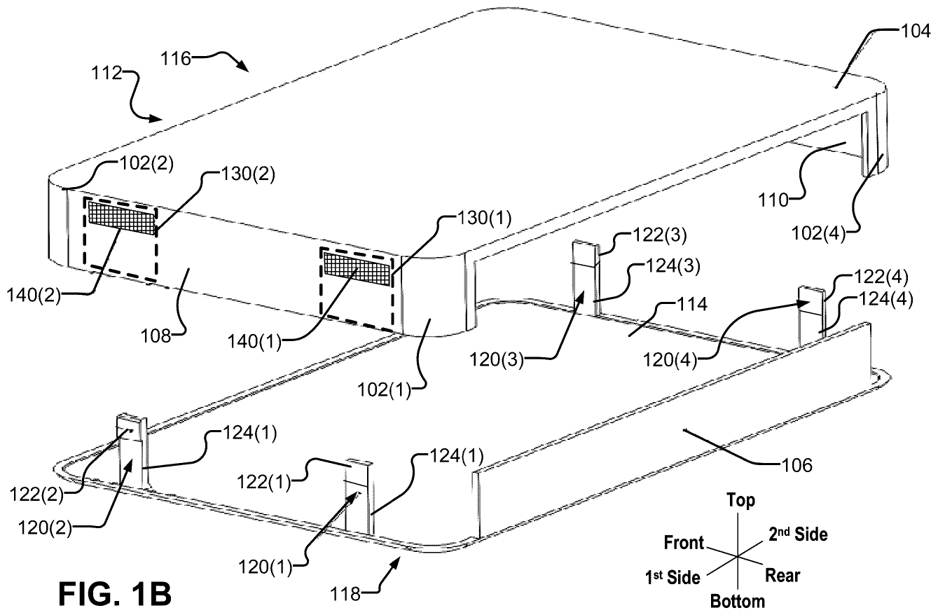

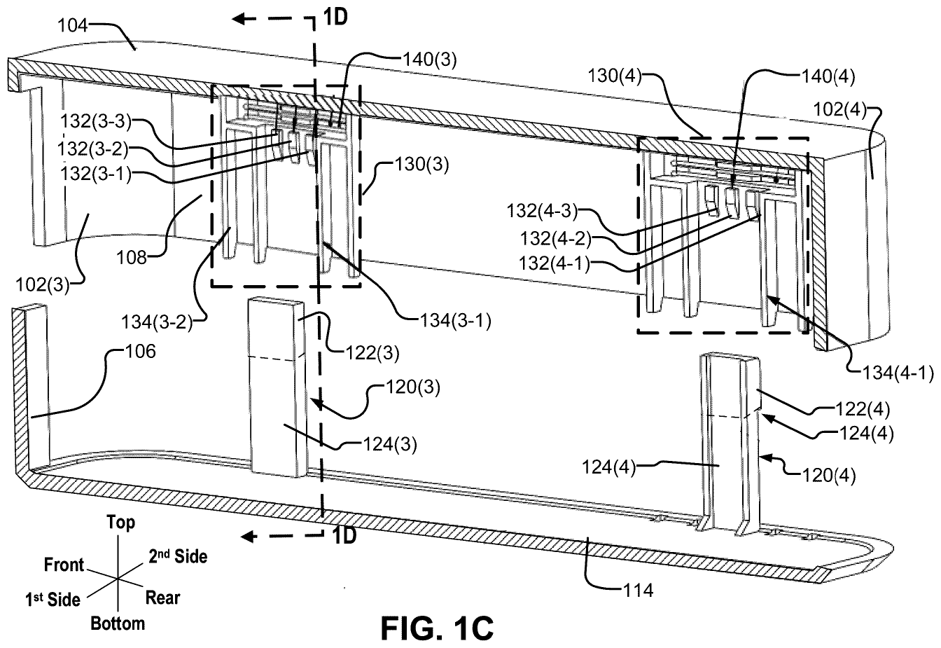

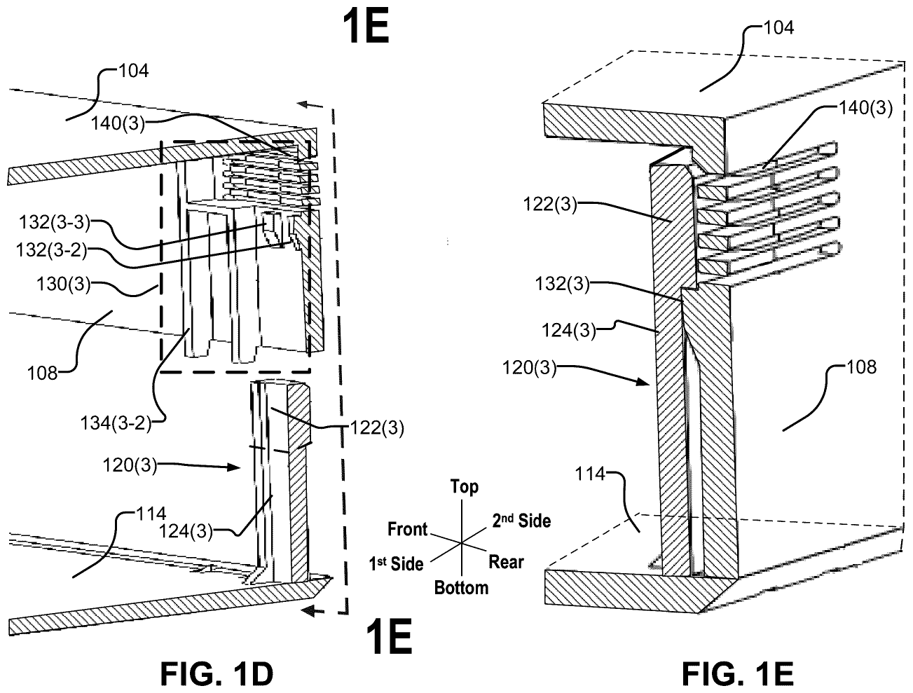

As shown in FIGS. 1A-1E and for at least one first implementation of the present disclosure, an enclosure may be configured as a cover flex window (“CFW”) enclosure 100. A CFW enclosure 100 may include one or more CFW corner panels 102(m) (where “m” is an integer), a CFW top panel 104, a CFW back panel 106, a CFW first side panel 108, a CFW second side panel 110, a CFW front panel 112, and a CFW bottom panel 114. For other non-shown implementations, a CFW enclosure may include other panels.

As shown in FIG. 1B, a first CFW panel assembly 116 may include the CFW top panel 104, CFW first side panel 108, CFW second side panel 110, CFW front panel 112, and four CFW corner panels 102. A second CFW panel assembly 118 may include the CFW bottom panel 114 and the CFW back panel 106.

The first CFW panel assembly 116 may be secured to the second CFW panel assembly 118 by use of one of one or more first fasteners, such as one or more CFW clip assemblies 120, and one or more respectively corresponding second fasteners, such as one more CFW clip stop assemblies 130. For at least one implementation, the CFW clip stop assemblies 130 may be located on interior faces of one or more of vertical panels included in the first CFW panel assembly 116 and the respectively corresponding CFW clip assemblies 120 may be located on the CFW bottom panel 114.

As shown in FIG. 1B, four CFW clip assemblies 120 are positioned on the CFW bottom panel 114 and include a first CFW clip assembly 120(1), a second CFW clip assembly 120(2), a third CFW clip assembly 120(3), and a fourth CFW clip assembly 120(4). For at least one implementation, the CFW clip assemblies 120 may be formed from a flexible material such as a resilient plastic or the like. A CFW clip assembly 120 may include a CFW clip top portion 122(m) that protrudes from a CFW clip bottom portion 124. The reference to a CFW clip top portion 122 and a CFW clip bottom portion 124 is provided herein for ease of identification and not for purposes of limitation. The CFW clip top portion 122 herein is distinguishable from a CFW clip bottom portion 124 based on the functions thereof with the CFW clip top portion 122 being configured for engagement and coupling with corresponding CFW clip stop assemblies 130 while the CFW clip bottom portion 124 is configured for flexion and extension of the CFW clip assembly 120 so as to facilitate controlled (dis)engagement and (un)coupling of a given CFW clip assembly 120 with a corresponding CFW clip stop assembly 130.

As shown in FIG. 1C, a CFW clip bottom portion 124 may be configured as a solid member for the third CFW clip bottom portion 124(3) or as a U-shaped member for the fourth CFW clip bottom portion 124(4). Other configurations of CFW clip bottom portions 124 may be used in other implementations of the present disclosure. As further shown in FIG. 1C, a CFW clip top portion 122 may include a CFW clip ridge 123(4), as shown for the fourth CFW clip assembly 120(4), or not include a CFW clip ridge as illustrated by the third CFW clip assembly 120(3) where a CFW clip ridge is not shown. Other configurations of CFW clip top portions 122 may be used in other implementations of the present disclosure.

For at least one implementation, a CFW clip stop assembly 130 may include one or more CFW clip stop ridges 132 and one or more CFW clip stop walls 134. The CFW clip stop assembly 130 may be configured for engaging and coupling with a CFW clip assembly 120. For at least one implementation, the one or more CFW clip stop ridges 132 for a given CFW clip stop assembly 130 may be configured for engagement with a CFW clip ridge 123 for a corresponding CFW clip assembly 120.

For at least one implementation, the CFW clip stop walls 134 may be rigid members that prevent flexion of a corresponding CFW side panel during securing and unsecuring of a CFW enclosure 100. More specifically and not by limitation, the third CFW clip stop assembly 130(3), as shown in FIGS. 1C-1E, may include a third CFW clip stop ridge 132(3-1), a third CFW clip stop ridge 132(3-2), a third CFW clip stop ridge 132(3-3), a third CFW clip stop first wall 134(3-1), and a third CFW clip stop second wall 134(3-2). The first CFW clip stop assemblies 130(1), second CFW clip stop assemblies 130(2), and fourth CFW clip stop assemblies 130(4) may be similarly configured.

The CFW enclosure 100 may include a CFW window 140 that corresponds to locations of the CFW clip stop assemblies 130. A CFW window 140 may include a flexible grid pattern (as shown), which facilitates air flow into the internal environment when the enclosure is secured and flexion of the CFW window 140 to facilitate flexion of an upper portion of a corresponding CFW clip top portion 122 from one or more respectively corresponding CFW clip stop ridges 132. For example, and with respect to a secured CFW enclosure 100, upon applying an inward pressure on the second CFW window 140(2), a CFW clip top portion 122(2) flexes inwards a distance to clear the corresponding CFW clip stop ridges 132(2-1), 132(2-2) and 132(2-3) such that, when corresponding forces are applied to each of the CFW windows 140(1-4), the first CFW panel assembly 116 may be raised relative to the second CFW panel assembly 1118 and access to the interior environment provided.

It is to be appreciated that a given implementation of a CFW enclosure may include any number of CFW clips assemblies 120, CFW clip stop assemblies 130, and CFW windows 140, herein, collectively a “CFW fastening system”). As shown in FIG. 1A, an implementation may include two CFW fastening systems located on a CFW first side panel 108 and no CFW fastening systems located on a CFW second side panel 110. For such a configuration, securing of the CFW enclosure 100 along the CFW second side panel 110 may include use of any fasteners.

A method for ready release of a secured CFW enclosure 100 may include, as a first CFW operation, an application of first force along the CFW first side panel 108 at the first CFW window 140(1) and a corresponding (in time) application of a second force along the CFW second side panel 110 at the fourth CFW window 140(4). The first force and the second force may be substantially equivalent so as to prevent a dislocation or rotation of the CFW enclosure.

While the first and second forces are being applied, a second CFW operation may include raising the first CFW panel assembly 116 above the second CFW panel assembly 118 such that the first CFW clip top portion 122(1) clears the corresponding first CFW clip stop ridge(s) 132(1-n) (where “n” is an integer) while the fourth CFW clip top portion 122(4) clears the corresponding fourth CFW clip stop ridges(s) 132(4-n).

A third CFW operation may include application of a third force along the CFW first side panel 108 at the second CFW window 140(2) and a corresponding (in time) application of a fourth force along the CFW second side panel 110 at the third CFW window 140(3). The third force and the fourth force may be substantially equivalent so as to prevent a dislocation or rotation of the CFW enclosure.

While the third and fourth forces are being applied, a fourth CFW operation may include raising the first CFW panel assembly 116 above the second CFW panel assembly 118 such that the second CFW clip top portion 122(2) clears the corresponding second CFW clip stop ridges(s) 132(2-n) while the third CFW clip top portion 122(3) clears the corresponding third CFW clip stop ridge(s) 132(3-n).

A fifth CFW operation may include raising the first CFW panel assembly 116 above and away from the second CFW panel assembly 118 and thereby gaining access to the interior environment of the CFW enclosure 100.

A method for securing a CFW enclosure 100 may include a first operation of aligning a first CFW panel assembly 116, having one or more CFW clip stop assemblies 130(m) relative to a second CFW panel assembly 118, having a corresponding number of CFW clips assemblies 120(m), such that the CFW clip stop assemblies 130(m) are above (in a “Top” direction for the coordinate system shown in FIGS. 1A-1E), the CFW clip assemblies 120(m). The method may include a second operation of applying a downward force (in the “bottom” direction for the coordinate system shown in FIGS. 1A-1E) until the CFW clip stop ridges 132(m) engage with the corresponding CFW clip ridges 123(m) and thereby secure the first CFW panel assembly 116 to the second CFW panel assembly 118.

It is to be appreciated that a CFW enclosure 100 provides various advantages over prior art configurations including providing access locations, via the CFW windows 140, near the top of an electronic device enclosure, and thereby enabling a technician to place the electronic device on a work bench or other flat surface and not having to handle the electronic device while unsecuring the enclosure. Further, the CFW enclosure 100 facilitates an aesthetic appearance due to the fastening mechanisms (the combination of the CFW clip assemblies 120 with the CFW clip stop assemblies 130 being internal to the CFW enclosure 100. Such aesthetic appearance also discourages non-technician access to the internal of the CFW enclosure 100 as a visibly apparent access point is not presented on the external portions of the CFW enclosure 100. Further, the CFW enclosure 100 may include CFW clip assemblies 120 and corresponding CFW clip stop assemblies 130 that are located in the CFW corner panels 102 and thereby increase, due to the CFW clip stop walls 134 the structural rigidity of a CFW enclosure 100.

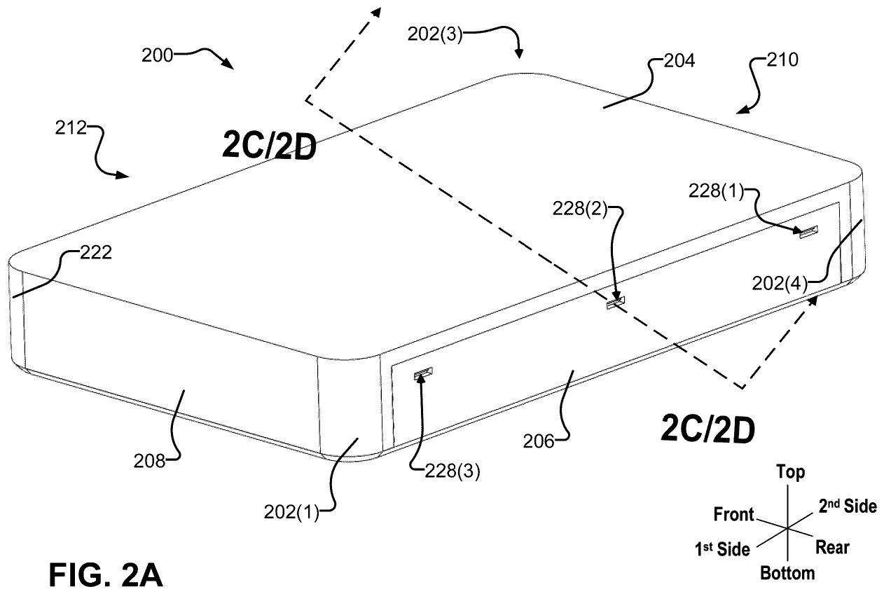

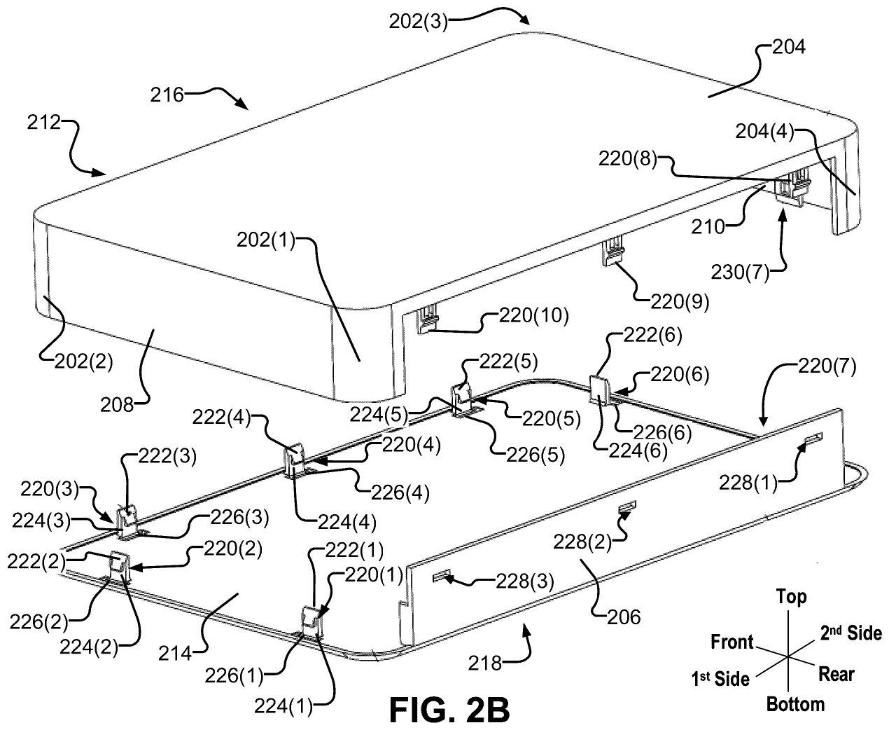

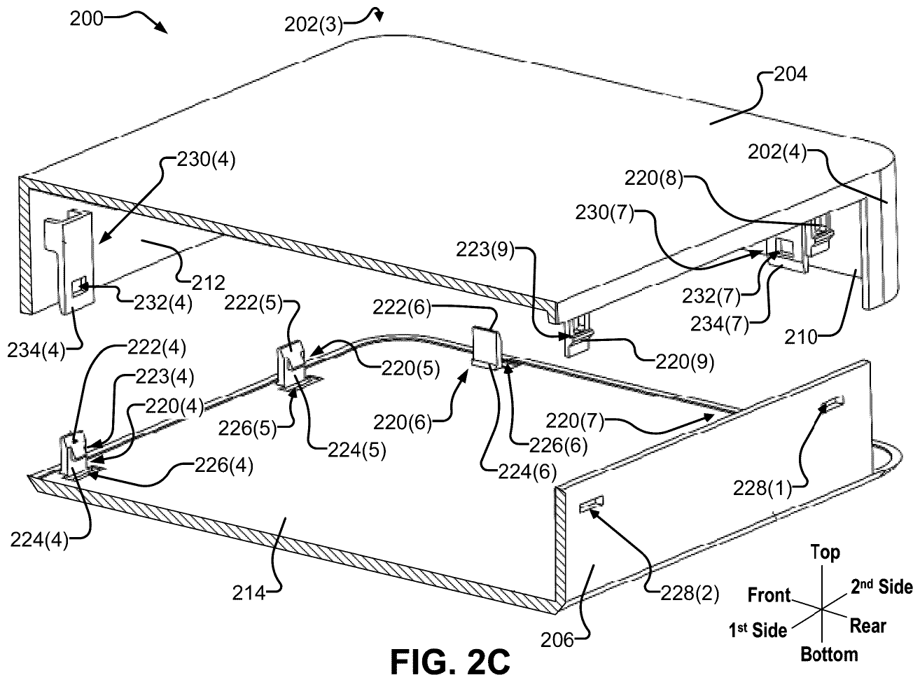

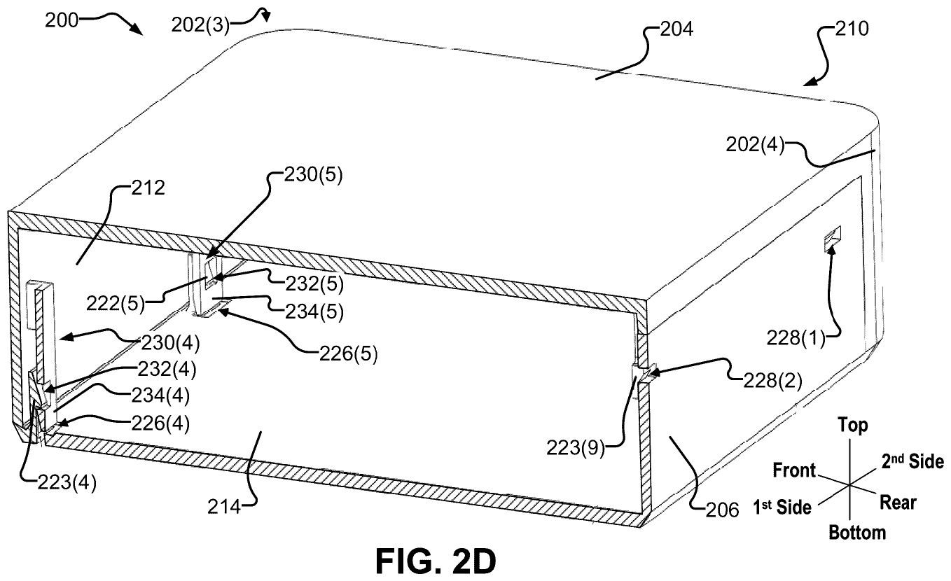

As shown in FIGS. 2A-2D and for at least one first implementation of the present disclosure, an enclosure may be configured as a cover flex clip (“CFC”) enclosure 200. A CFC enclosure 200 may include one or more CFC corner panels 202, a CFC top panel 204, a CFC back panel 206, a CFC first side panel 208, a CFC second side panel 210, a CFC front panel 212, and a CFC bottom panel 214. For other non-shown implementations, a CFC enclosure 200 may include other panels. As shown in FIG. 2B, a first CFC panel assembly 216 may include the CFC top panel 204, CFC first side panel 208, CFC second side panel 210, CFC front panel 212, and four CFC corner panels 202. A second CFC panel assembly 218 may include the CFC bottom panel 214 and the CFC back panel 206.

For at least one implementation, a CFC enclosure 200 may include one or more first fasteners, such as one or more CFC clip assemblies 220. For example, a CFC enclosure 200 may include a first CFC clip assembly 220(1), a second CFC clip assembly 220(2), a third CFC clip assembly 220(3), a fourth CFC clip assembly 220(4), a fifth CFC clip assembly 220(5), a sixth CFC clip assembly 2206(6), a seventh CFC clip assembly 220(7), an eighth CFC clip assembly 220(8), a ninth CFC clip assembly 220(9), and a tenth CFC clip assembly 220(10). A CFC clip assembly 220 may include a CFC clip top portion 222(m), a CFC clip ridge 223(m) (as shown, e.g., in FIG. 2C), and a CFC clip bottom portion 224(m). Any number of CFC clip assemblies 220 may be used for a given implementation, and the CFC clip assemblies 220 may be positioned and/or distributed about a perimeter of a CFC enclosure 200 so as to facilitate securing of a first CFC panel assembly 216 to a second CFC panel assembly 218.

For at least one implementation, a CFC clip assembly 220 may include two or more CFC access slots 226, such as a first CFC clip access slot 226(1), a second CFC clip access slot 226(2), a third CFC clip access slot 226(3), a fourth CFC clip access slot 2262(4), a fifth CFC clip access slot 226(5), a sixth CFC clip access slot 226(6), and a seventh CFC clip access slot 226(7). For at least one implementation a given CFC clip access slot 226, such as a first CFC clip access slot 226(1), corresponds to a given CFC clip assembly 220, such as the first CFC clip assembly 220(1).

For at least one implementation, a CFC enclosure 200 may include one or more second fasteners that correspond to one or more of the first fasteners used for a given implementation. For example, a second fastener may include a CFC hook assembly 230, such as a first CFC hook assembly 230(1), a second CFC hook assembly 230(2), a third CFC hook assembly 230(3), a fourth CFC hook assembly 230(4), a fifth CFC hook assembly 230(5), a sixth CFC hook assembly 230(6), and a seventh CFC hook assembly 230(7). Each CFC hook assembly 230 may include a CFC hook opening 232(m). As shown, one more CFC hooks assemblies 230 correspond to locations inside the CFC enclosure 200 at which a CFC clip assembly 220, a first fastener, is located. For at least one implementation, a given CFC hook assembly 230, such as the first CFC hook assembly 230(1), corresponds to a given CFC clip assembly, such as the first CFC clip assembly 220(1). For at least one implementation, a given CFC hook assembly 230, such as the first CFC hook assembly 230(1), may be provided on a panel of the first CFC panel assembly 216, such as the CFC front panel 212, while a CFC clip assembly 220 corresponding thereto, such as the first CFC clip assembly 220(1), may be provided on a panel of the second CFC panel assembly 218, such as the CFC bottom panel 214. It is to be appreciated that engagement of a given CFC clip assembly 220 with a given CFC hook assembly 230 secures, at least a portion of the first CFC panel assembly 216 to the second CFC panel assembly 218.

As used herein, a CFC clip access slot 226, a CFC clip assembly 220, and a CFC hook assembly 230 are deemed to “correspond” to each other when an insertion of a tool into the given CFC clip access slot 226 results in a bending or other movement of a given CFC hook bottom portion 234(m) such that a CFC clip top portion 222 otherwise coupled to the given CFC hook assembly 230 is no longer coupled thereby.

For at least one implementation, a CFC clip access slot 226 may align with a CFC hook assembly 230 such that when a given CFC hook bottom portion 234 and a given CFC clip top portion 222 are engaged with each other (and thereby securing at least a portion of a first CFC panel assembly 216 to a second CFC panel assembly 218), a CFC hook bottom portion 234(m) penetrates into at least a portion of the corresponding CFC clip access slot 226(m) so as to prevent entry of undesired substances into the CFC enclosure 200 when the CFC enclosure 200 is in a secured/closed (as opposed to unsecured/opened) configuration. For at least one implementation, the penetration of a given CFC hook bottom portion 234(m) seals the CFC enclosure 200 so as to prevent intrusion of pollutants into the interior of the CFC enclosure 200, via the given CFC clip access slot 226(m). For at least one implementation, the pollutant may be one or more of a fluid, air, dust, user's fingers, foreign objects, or other items that absent the seal would expose the interior of the CFC enclosure 200 to penetration by foreign objects.

For at least one implementation, a CFC enclosure 200 may include an alternative second fastener, such as a CFC access and retention slot 228. For example, a CFC enclosure 200 may include a first CFC access and retention slot 228(1), a second CFC access and retention slot 228(2), and a third CFC access and retention slot 228(3). A CFC access and retention slot 228 may correspond to a CFC clip assembly 220 and may be utilized in place of a CFC hook assembly 230 for coupling with a CFC clip assembly 220—a first fastener. For example, a first CFC access and retention slot 228(1) may correspond to an eighth CFC clip assembly 220(8). For at least one implementation, a CFC access and retention slot 228 is deemed to “correspond” to a given CFC clip assembly 220 when an insertion of a tool into the given CFC access and retention slot 228 results in a pushing of a CFC clip top portion 222, then lodged into the CFC access and retention slot 228, out of the CFC access and retention slot 228 and thereby releasing, at least a portion of, the first CFC panel assembly 216 from the second CFC panel assembly 218.

For at least one implementation, a CFC access and retention slot 228 may align with a CFC clip top portion 222 such that when a given CFC clip top portion 222(m) penetrates, at least a portion of, a corresponding CFC access and retention slot 228(m), a first entry of undesired substances into the CFC enclosure 200 is inhibited when the CFC enclosure 200 is in a secured/close (versus unsecured/opened) configuration. For at least one implementation, the penetration of a given CFC clip top portion 222(m) into the given and corresponding CFC access and retention slot 228(m) seals the CFC enclosure 200 so as to prevent intrusion of pollutants into the interior of the CFC enclosure, via the given CFC access and retention slot 228.

A method for ready release of a secured CFC enclosure 200 may include a first operation of inserting one or more tool prongs into the one or more CFC access slots 226 located on a CFC bottom panel 214; wherein upon insertion of the tool prongs into the respective CFC clip access slots 226, a first set of one or more CFC clip assemblies 220 corresponding to the one or more CFC access slots 226 are released from the corresponding CFC hook assemblies 230.

The method may include a second operation of inserting one or more second tool prongs into one or more CFC access and retention slots 228; wherein upon insertion of the tool prongs into the respective CFC access and retention slots 228, CFC clip assemblies 220 corresponding to the CFC access and retention slots 228 are dislodged therefrom. For at least one implementation, the second operation may be performed while, per the first operation, the first set of CFC clip assemblies 220 are released from the respectively corresponding CFC hook assemblies 230. For at least one implementation, the second operation may be performed before the first operation is performed.

The method may include a third operation of raising, or otherwise moving, a first CFC panel assembly 2164 away from a second CFC panel assembly 218 so that the interior of the CFC enclosure 200 may be accessed. For at least one implementation, the third operation may be performed while, per the first operation, the first set of CFC clip assemblies 220 are released from the respectively corresponding CFC hook assemblies 230.

A method for securing a CFC enclosure 200 may include a first operation of aligning a first CFC panel assembly 216, having one or more CFC hook assemblies 230(m) relative to a second CFC panel assembly 218, having a corresponding number of CFC clip assemblies 220(m), such that the CFC clip assemblies 220(m) are below (in a “Bottom” direction for the coordinate system shown in FIGS. 2A-2D), the CFC hook assemblies 230(m). The method may include a second operation of applying a downward force (in the “bottom” direction for the coordinate system shown in FIGS. 2A-2D) until the CFC hook assemblies 230(m) engage with the corresponding CFC clip assemblies 220(m) and thereby secure the first CFC panel assembly 216 to the second CFC panel assembly 218. For at least one implementation, during the second operation one or more second set of CFC clip top portions 222(m) may engage with corresponding one or more CFC access and retention slots 228, which when so engage further secures one or more panels of a CFC enclosure 200 to one more other panels of the CFC enclosure 200.

It is to be appreciated that a CFC enclosure 200 provides various advantages over prior art implementations including no visible opening for engagement, by a user, with a CFC clip assembly 220, via the CFC front panel 212, the CFC first side panel 208, the CFC second side panel 210, or the CFC back panel 206. Further, the CFC enclosure 200 provides an enclosure where openings in the CFC enclosure 200, such as those provided by the CFC access slots 226 and CFC access and retention slots 228, are covered portions of the CFC hook assemblies 230 and thereby sealed so as to prevent intrusion of pollutants into the interior of the CFC enclosure 200.

Another advantage of a CFC enclosure 200 is a requirement for a tool or die assembly configured to release the first CFC panel assembly 216 from the second CFC panel assembly 218 by substantially simultaneous penetrations of multiple tool prongs into the multiple CFC access slots 226 and/or CFC access and retention slots 228 used for a given implementation. Another advantage is the locating of the CFC hook assemblies 230 and CFC clip assemblies 220 along an interior perimeter for a CFC enclosure 200 increases the structural integrity of the CFC enclosure 200. Another advantage is the lack of use of a screw or other fastener to secure the first CFC panel assembly 2164 to the second CFC panel assembly 218. Such non-use of a screw or other fastener facilitates ready release of the CFC enclosure 200 from a secured to non-secured/open configuration, with use of a corresponding tool or die assembly configured to facilitate opening of a secured CFC enclosure 200.

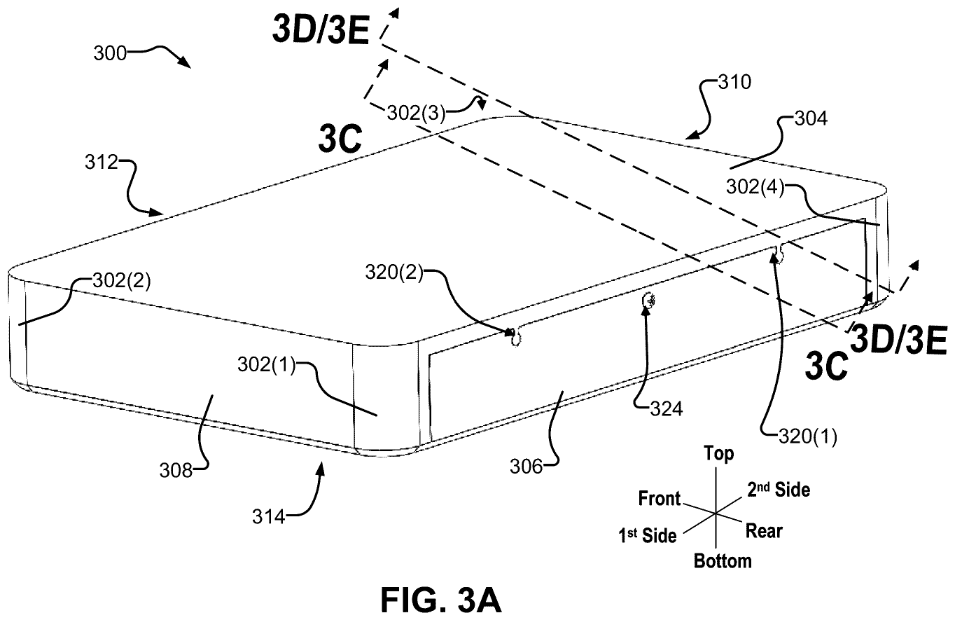

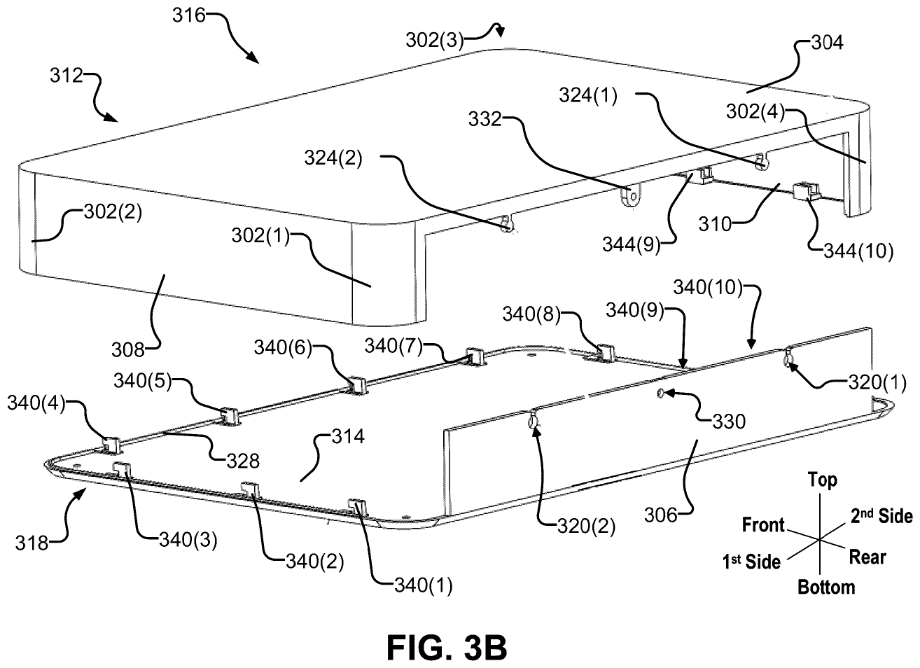

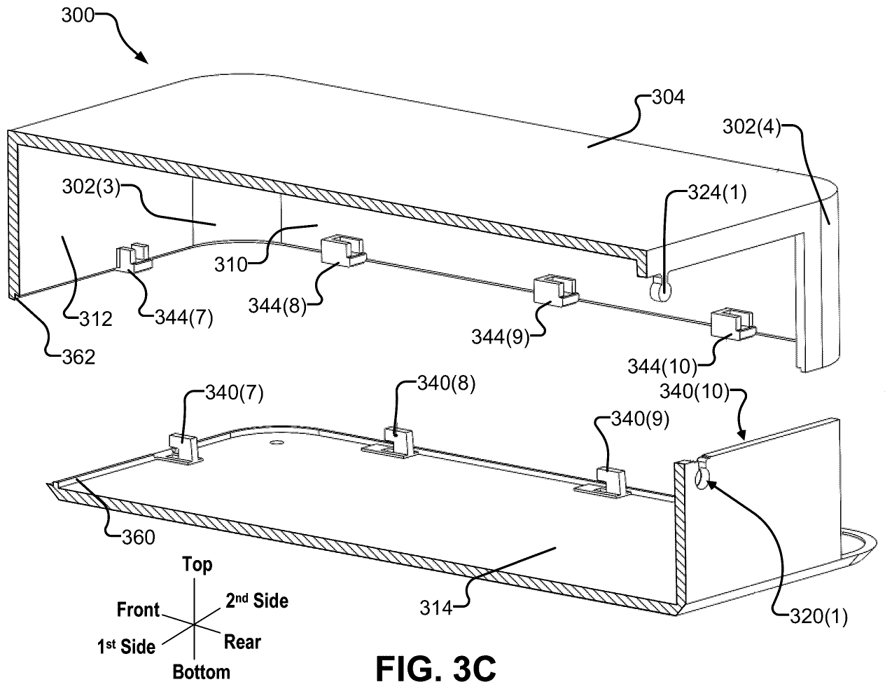

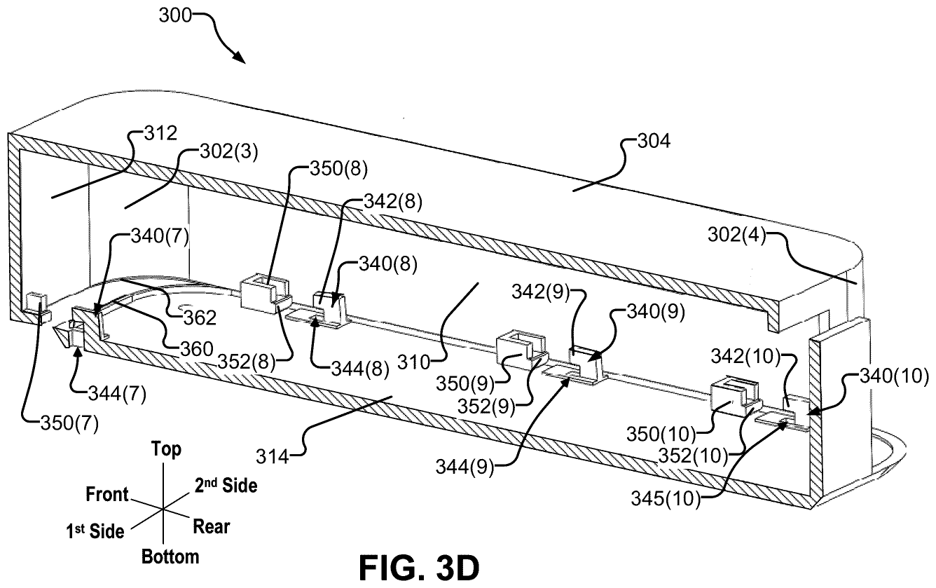

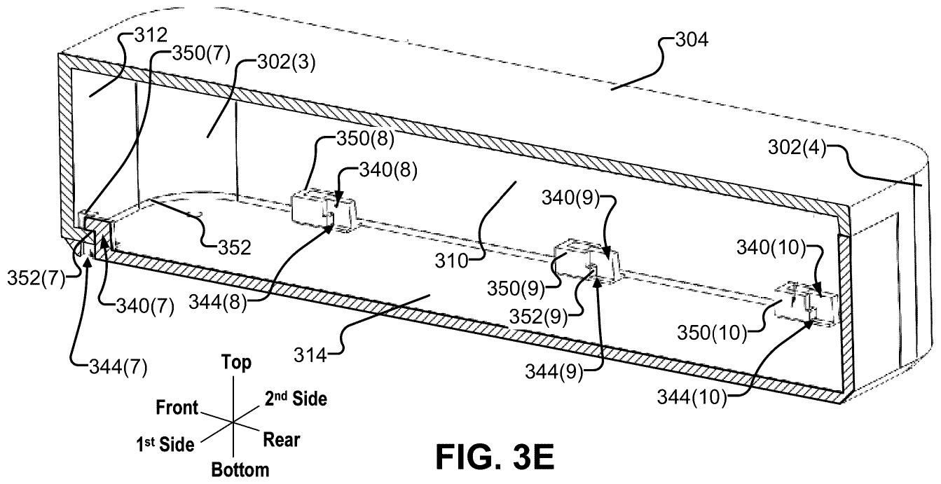

As shown in FIGS. 3A-3E and for at least one third implementation of the present disclosure, an enclosure may be configured as a cover slide and hook clip (“CSHC”) enclosure 300. A CSHC enclosure 300 may include one or CHSC corner panels 302(m), a CSHC top panel 304, a CSHC back panel 306, a CSHC first side panel 308, a CSHC second side panel 310, a CSHC front panel 312, and a CSHC bottom panel 314. For other implementations, a CSHC enclosure 300 may include other panels.

As shown in FIG. 3B, a first CSHC panel assembly 316 may include the CSHC top panel 304, CSHC first side panel 308, CSHC second side panel 310, CSHC front panel 312, and four CSHC corner panels 302. A second CSHC panel assembly 318 may include a CSHC bottom panel 314 and the CSHC back panel 306.

For at least one implementation, a CSHC enclosure 300 may include, as one or more first fasteners, one or more CSHC prong holes 320, such as a first CSHC prong hole 320(1) and a second CSHC prong hole 320(2). As shown in FIG. 3A, the CSHC prong holes(s) 320 may be located on the CSHC back panel 306. For other implementations, the CSHC prong hole(s) 320 may be located on other CSHC panels. The CSHC prong holes 320 may be configured for respective coupling with one or more second fasteners, such as a CSHC prong 324, such as a first CSHC prong 324(1) and a second CSHC prong 324(2), as shown in FIG. 3B. The CSHC prongs 324, when coupled in a CSHC prong hole 320 facilitate a locking type engagement, in a bottom to a top direction, of the first CSHC panel assembly 316 with the second CSHC panel assembly 318.

A CSHC enclosure 300 may include, as one or more first fasteners, one or more CSHC screw holes 330, with one being show in FIG. 3B, and a corresponding CSHC screw boss 322. For at least one implementation, a CSHC screw boss 332 may be located on a CSHC top panel 304 and a CSHC screw hole 330 may be located on a CSHC back panel 306. A second fastener, such as a screw 334, may be inserted into the CSHC screw hole 330 and the CSHC screw boss 332 and tightened so that the CSHC back panel 306 is fastened to the CSHC top panel 304. It is to be appreciated that any number of pairs of CSHC screw holes 330, CSHC screw bosses 332 and screws 334 may be used for a given implementation of the present disclosure to secure a first CSHC panel assembly 316 to the second CSHC panel assembly 318.

A CSHC enclosure 300 may include, as one or more first fasteners, one or more CSHC hook assemblies 340, such as a first CSHC hook assembly 340(1), a second CSHC hook assembly 340(2), a third CSHC hook assembly 340(3), a fourth CSHC hook assembly 340(4), a fifth CSHC hook assembly 340(5), a sixth CSHC hook assembly 340(6), a seventh CSHC hook assembly 340(7), an eighth CSHC hook assembly 340(8), a ninth CSHC hook assembly 340(9), and a tenth CSHC hook assembly 340(10).

A CSHC hook assembly 340 may be paired with one or more second fasteners, such as a CHSC hook cavity assembly 350, such as a first CSHC hook cavity assembly 350(1), a second CSHC hook cavity assembly 350(2), a third CSHC hook cavity assembly 350(3), a fourth CSHC hook cavity assembly 350(4), a fifth CSHC hook cavity assembly 350(5), a sixth CSHC hook cavity assembly 350(6), a seventh CSHC hook cavity assembly 350(7), an eighth CSHC hook cavity assembly 350(8), a ninth CSHC hook cavity assembly 350(9), and a tenth CSHC hook cavity assembly 350(10). For at least one implementation, the CSHC hook assemblies 340(m) are provided on a panel for a first CSHC panel assembly 316 while the CSHC hook cavity assemblies 350(m) are provided on a second panel for a second CSHC panel assembly 318. Any number and/or configuration of pairings of CSHC hook assemblies 340 and CSHC hook cavity assemblies 350 may be used for a given implementation of the present disclosure.

As shown in FIGS. 3D and 3E, to secure the first CSHC panel assembly 316 to the second CSHC panel assembly 318 the corresponding pairings of CSHC hook assemblies 340 and CSHC hook cavity assemblies 350 may be aligned such that a sliding engagement of the first CSHC panel assembly 316 relative to the second CSHC panel assembly 318 may secure the panel assemblies to each other when slid in a first direction (such as in the front to rear direction) or release the panel assemblies from each other when slid in a second/opposite direction.

For at least one implementation, a CSHC hook cavity assembly 350 may include a CSHC hook cavity ridge 352, such as the seventh CSHC hook cavity ridge 352(7), eighth CSHC hook cavity ridge 352(8), ninth CSHC hook cavity ridge 352(9), and tenth CSHC hook cavity ridge 352(10), as shown in FIG. 3D. A CSHC hook cavity ridge 352(m) may be configured for engagement with a CSHC hook lip 342, such as the ninth CSHC hook lip 342(9), as shown in FIG. 3D.

A CSHC enclosure 300 may further include a CSHC hook access slot 344, such as a first CHSC hook access slot 344(1), a second CSHC hook access slot 344(2), a third CSHC hook access slot 344(3), a fourth CSHC hook access slot 344(4), a fifth CSHC hook access slot 344(5), a sixth CSHC hook access slot 344(6), a seventh CSHC hook access slot 344(7), an eighth CSHC hook access slot 344(8), a ninth CSHC hook access slot 344(9), and a tenth CSHC hook access slot 344(10). When a CSHC enclosure 300 is in a secured/closed configuration, a CSHC hook access slot 344 provides an access opening by which a tool or other implement may be inserted, and a force applied so as to facilitate movement of a CSHC hook lip 342 away from a CSHC hook cavity ridge 352 and the slidable disengagement of the first CSHC panel assembly 316 from the second CSHC panel assembly 318. When multiple CSHC hook assemblies 340 and CSHC hook cavity assemblies 350 are used for a given implementation, a corresponding multi-prong tool assembly may be used to apply a force upon each of the CSHC hook lips 342(m) so as to facilitate separation of the CSHC hook lips 342(m)1 above the corresponding CSHC hook cavity ridge 352 used for the given implementation. For at least one implementation, a CSHC hook cavity ridge 352 may seal a CSHC hook access slot 344, when a CSHC enclosure 300 is in a secured/closed configuration, so as to prevent intrusion of pollutants into the interior of the CSHC enclosure 300, via the given CSHC hook access slot 344.

For at least one implementation, a CSHC panel may include a first ridge that is configured for coupling with a corresponding second ridge on a second CSHC panel. The first ridge may function as a first fastener and the second ridge may function as a second fastener. For example, in the non-limiting implementation shown in FIGS. 3A-3E, the CSHC bottom panel 314 may include a CSHC bottom panel ridge 360 that is configured for coupling with a CSHC front panel ridge 362 provided by the CSHC front panel 312. For other implementations, other or no combinations of panel ridges may be used. The corresponding panel ridges, if any, may provide a seal for the CSHC enclosure 300 when in a secured/closed configuration. Gaskets or other membranes may be located along a panel ridge and facilitate further sealing of a first CSHC panel assembly 316 with a second CSHC panel assembly 318.

A method for securing a CSHC enclosure 300 may include a first operation of aligning a first CSHC panel assembly 316, having one or more CSHC hook assemblies 340(m), relative to a second CSHC panel assembly 318, having a corresponding number of CSHC hook cavity assemblies 350(m), such that the CSHC hook assemblies 340(m) are aligned (along a front-rear plane for the coordinate system shown in FIGS. 3A-3E), with the CSHC hook cavity assemblies 350(m). The method may include a second operation of applying a sliding (front to rear) force until the CSHC hook lips 342(m) engage with the corresponding CSHC hook cavity ridges 352(m) and thereby secure the first CSHC panel assembly 316 to the second CSHC panel assembly 318. For at least one implementation, during the second operation one or more second set of CSHC hook access slots 344 may engage with corresponding one or more elements of a CSHC hook cavity assembly 350(m), which when so engaged further secure one or more panels of a CSHC enclosure 300 to one more other panels of the CSHC enclosure 300.

A method for releasing a secured CSHC enclosure 300 may include an optional first operation of removing any screw 334, if any, inserted into a CSHC screw hole 330 and CSHC screw boss 332. A non-optional first operation may include aligning the secured CSHC enclosure 300 in a tool configured to include one or more prongs, which can be inserted into respectively corresponding CSHC hook access slots 344(m). A second operation may include applying a pressure, by the prongs, upon each of the CSHC hook cavity ridge 352(m) used for a given implementation of a CSHC enclosure 300 so as to dislocate the corresponding CSHC hook lip 342(m) from the CSHC hook cavity ridge 352(m). A third operation may include sliding the first CSHC panel assembly 316 away from the second CSHC panel assembly 318. The third operation may be performed in conjunction with the second operation or separate from the second operation.

It is to be appreciated that a CSHC enclosure 300 provides various advantages over prior art implementations including no visible opening for engagement, by a user, with a CSHC hook assembly 340, via CSHC front panel 312, CSHC first side panel 308, CSHC second side panel 310, or the CSHC back panel 306. Further, the CSHC enclosure 300 provides an enclosure where, when in a secured/closed configuration, engagement openings, such as those provided by the CSHC hook access slots 344, are covered by elements of the corresponding CSHC hook cavity assembly 350 and thereby sealed so as to prevent intrusion of pollutants into the interior of the CSHC enclosure 300. Another advantage is the locating of the CSHC hook assemblies 340 320 and CSHC hook cavity assemblies 350 along an interior perimeter for a CSHC enclosure 300 increases the structural integrity of the CSHC enclosure 300. Another advantage is the option to use a screw 334 or other fastener to secure the first CSHC panel assembly 316 to the second CSHC panel assembly 318. Another advantage is the use of the CSHC prong holes 320 with the corresponding CSHC prongs 324 further stabilize the CSHC back panel 306 during the sliding engagements and disengagements of the first CSHC panel assembly 316 with the second CSHC panel assembly 318.

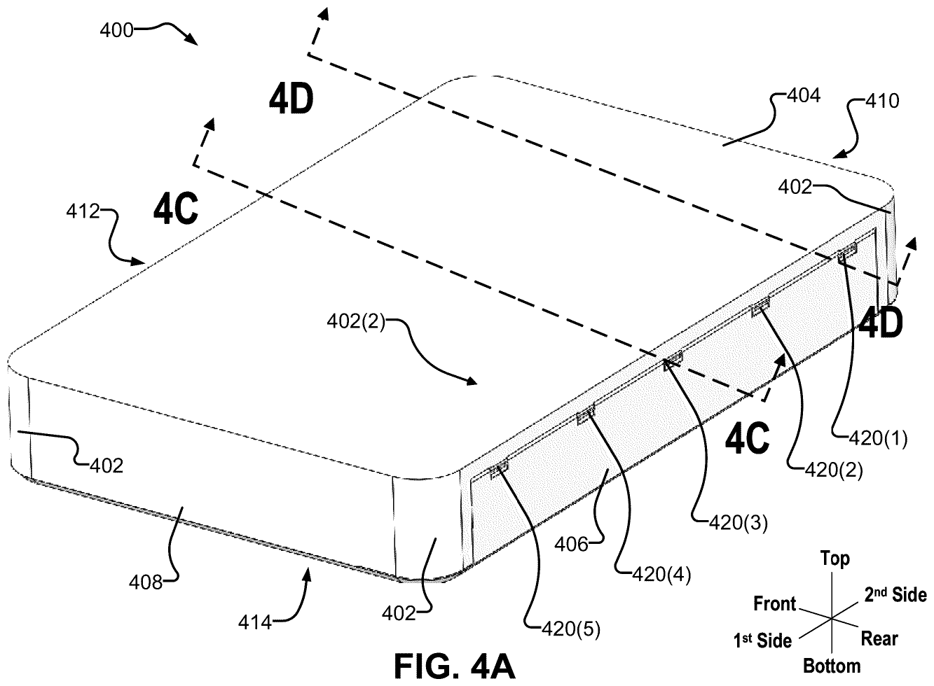

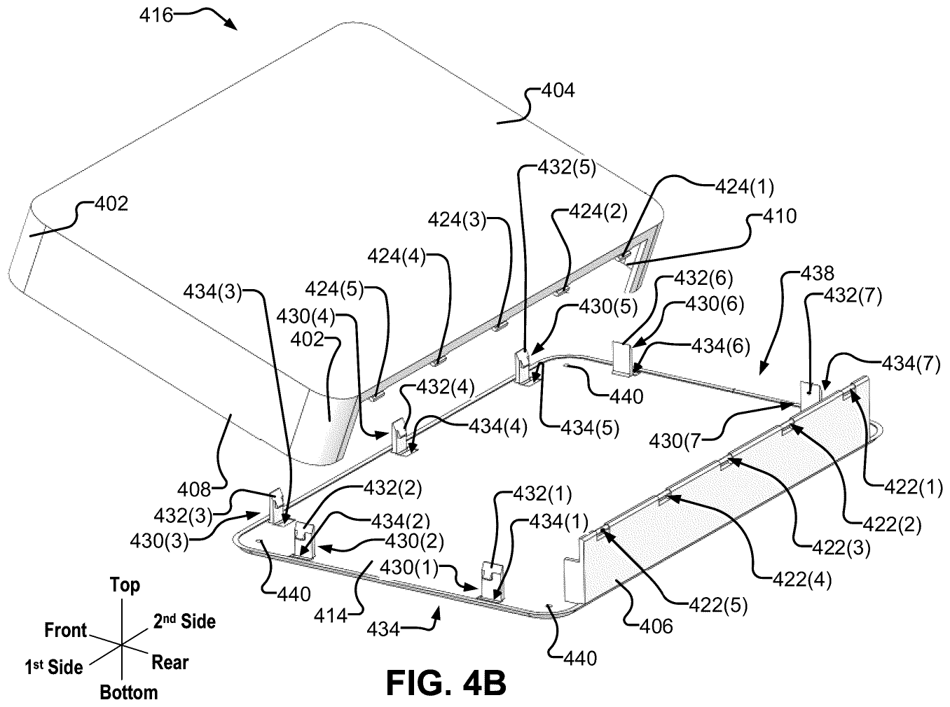

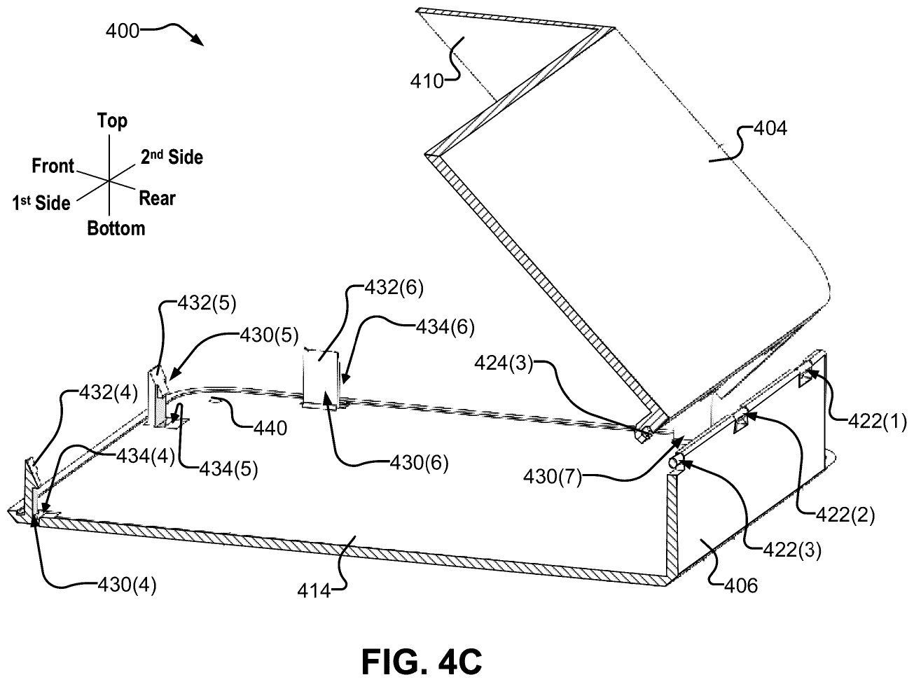

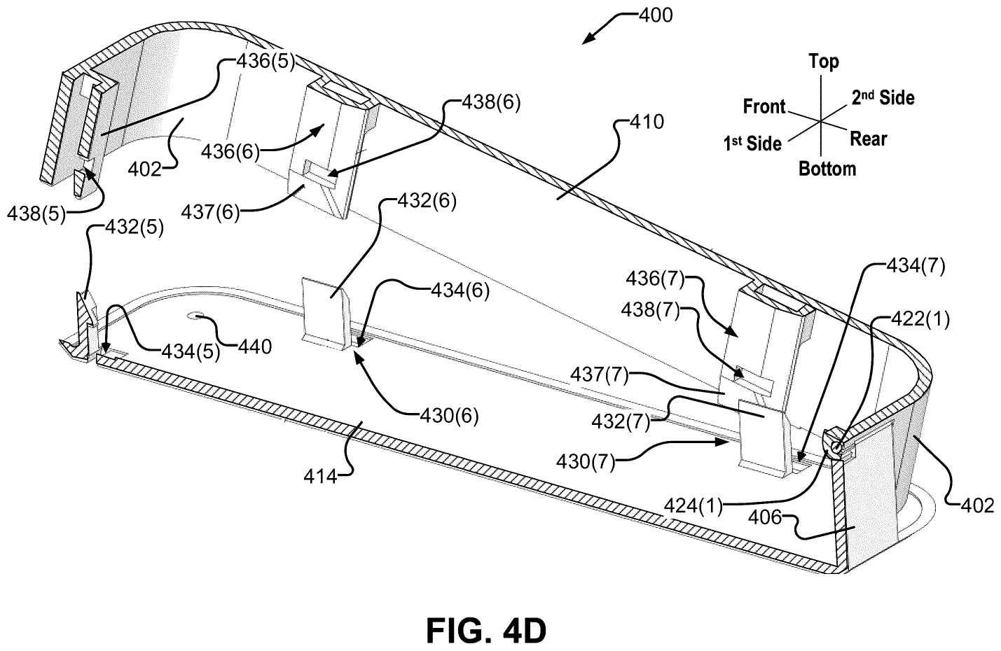

As shown in FIGS. 4A-4D and for at least one fourth implementation of the present disclosure, an enclosure may be configured as a hinged cover with flex clip (“HCFC”) enclosure 400. An HCFC enclosure 400 may include one or more HCFC corner panels 402, an HCFC top panel 404, an HCFC back panel 406, an HCFC first side panel 408, an HCFC second side panel 410, an HCFC front panel 412, and an HCFC bottom panel 414. For other non-shown implementations, an HCFC enclosure 400 may include other panels. As shown in FIG. 4B, a first HCFC panel assembly 416 may include the HCFC top panel 404, HCFC first side panel 408, HCFC second side panel 410, HCFC front panel 412, and four HCFC corner panels 402. A second HCFC panel assembly 418 may include a HCFC bottom panel 414 and the HCFC back panel 406. For other implementations, other combinations of panels may form two or more HCFC panel assemblies.

For at least one implementation, an HCFC enclosure 400 may include, as one or more first fasteners, one or more HCFC hinges 420, such as a first HCFC hinge 420(1), a second HCFC hinge 420(2), a third HCFC hinge 420(3), a fourth HCFC hinge 420(4), and a fifth HCFC hinge 420(5). As shown in FIG. 4A, the HCFC hinges 420 are located on the HCFC back panel 406. For other implementations, the one or more HCFC hinges 420 may be located on other HCFC panels.

An HCFC hinge 420 may include an HCFC hinge shaft 422, such as first HCFC hinge shaft 422(1), a second HCFC hinge shaft 422(2), a third HCFC hinge shaft 422(3), a fourth HCFC hinge shaft 422(4), and a fifth HCFC hinge shaft 422(5).

An HCFC hinge 420 may be configured for respective coupling of the given HCFC hinge shaft 422 with, as one or more second fasteners, an HCFC hinge clip 424, such as a first HCFC hinge shaft 422(1) being configured for coupling with the first HCFC hinge clip 424(1), a second HCFC hinge shaft 422(2) configured for coupling with the second HCFC clip 424(2), a third HCFC hinge shaft 422(3) configured for coupling with the third HCFC hinge clip 424(3), a fourth HCFC hinge shaft 422(4) configured for coupling with the fourth HCFC hinge clip 424(4), and a fifth HCFC hinge shaft 422(5) configured for coupling with the fifth HCFC hinge clip 424(5).

As shown in FIGS. 4C and 4D and for at least one implementation of the present disclosure, a HCFC hinge 420 may be coupled with a corresponding HCFC hinge clip 424 by first aligning a first HCFC panel on which the HCFC hinge clip 424 is provided above a second HCFC panel on which the corresponding HCFC hinge 420 is provided. As shown for example and not be limitation in FIGS. 4A-4D, the HCFC hinge clip 424 is provided on an HCFC top panel 404 while the HCFC hinge 420 is provided on an HCFC back panel 406. It is to be appreciated that an HCFC hinge clip 424 and a corresponding HCFC hinge 420 may be provided on other HCFC panels which facilitate closing/securing and opening/unsecuring the HCFC enclosure 400 so as to permit or inhibit, as the case may be, access to an interior for the HCFC enclosure 400.

For at least one implementation, coupling of an HCFC hinge 420 with an HCFC hinge clip 424 may include a snapping or clicking type activity whereby a resilient and bendable portion of an HCFC hinge clip 424 expands to permit an inner concavity thereof to encircle substantially all of a diameter of a corresponding HCFC hinge shaft 422.

For at least one implementation, an HCFC enclosure 400 may include, as one or more first fasteners, two or more HCFC clip assemblies 430, such as a first HCFC clip assembly 430(1), a second HCFC clip assembly 430(2), a third HCFC clip assembly 430(3), a fourth HCFC clip assembly 430(4), a fifth HCFC clip assembly 430(5), a sixth HCFC clip assembly 430(6), and a seventh HCFC clip assembly 430(7). For at least one implementation, an HCFC clip assembly 430 includes an HCFC clip top portion 432 and an HCFC clip access slot 434. Any number of HCFC clip assemblies 430 may be used for a given implementation, and the HCFC clip assemblies 430 may be distributed about a perimeter of an HCFC enclosure 400 so as to facilitate securing of a first HCFC panel assembly 416 to a second HCFC panel assembly 418.

As shown in FIG. 4B, a first HCFC clip assembly 430(1) may include a first HCFC clip top 432(1) and a first HCFC clip access slot 434(1), a second HCFC clip assembly 430(2) may include a second HCFC clip top 432(2) and a second HCFC clip access slot 434(2), a third HCFC clip assembly 430(3) may include a third HCFC clip top 432(3) and a third HCFC clip access slot 434(3), a fourth HCFC clip assembly 430(4) may include a fourth HCFC clip top 432(4) and a fourth HCFC clip access slot 434(4), a fifth HCFC clip assembly 430(5) may include a fifth HCFC clip top 432(5) and a fifth HCFC clip access slot 434(5), a sixth HCFC clip assembly 430(6) may include a sixth HCFC clip top 432(6) and a sixth HCFC clip access slot 434(6), and a seventh HCFC clip assembly 430(7) may include a seventh HCFC clip top 432(7) and a seventh HCFC clip access slot 434(8).

For at least one implementation, an HCFC enclosure 400 may include, as one or more second fasteners, an HCFC hook 436 that includes an HCFC hook bottom portion 437(m) that corresponds to one of each of the HCFC clip assemblies 430 used for a given implementation. As shown in FIG. 4D, an HCFC hook 436 may include an HCFC hook opening 438, such the partially/cut-away shown fifth HCFC hook 436(5) having a fifth HCFC hook opening 438(5), the sixth HCFC hook 436(6) having a sixth HCFC hook opening 438(6), and the seventh HCFC hook 436(7) having a seventh HCFC hook opening 438(7). Also shown are sixth HCFC hook bottom portion 437(6) and seventh HCFC hook bottom portion 437(7). First through fourth HCFC hooks 436 are not shown but may be included in the implementation shown in FIGS. 4A-4D.

The one more HCFC hooks 436 used for a given implementation correspond to locations inside the HCFC enclosure 400 at which an HCFC clip assembly 430 is located. For at least one implementation, a location in an HCFC enclosure 400 for a given HCFC hook, such as the first HCFC hook 436(1), corresponds to a location of a given HCFC clip assembly 430 within a given HCFC enclosure 400, such as the location of the first HCFC clip assembly 430(1). For at least one implementation, a given HCFC hook 436, such as the sixth HCFC hook 436(6), may be provided on a panel of the first HCFC panel assembly 416, such as the HCFC second side panel 410, while an HCFC clip assembly 430 corresponding thereto, such as the sixth HCFC clip assembly 430(6), may be provided on a panel of the second HCFC panel assembly 418, such as the HCFC bottom panel 414. It is to be appreciated that engagement of a given HCFC clip assembly 430 assembly with a given HCFC hook 436 secures, at least a portion of the first HCFC panel assembly 416 to the second HCFC panel assembly 418 by insertion of the given HCFC clip top 432 into the corresponding HCFC hook opening 438. A release of the first HCFC panel assembly 416 from the second HCFC panel assembly 418 may be performed by a human or automate/semi-automated machine tool by removal of a given HCFC clip top 432 from a correspond HCFC hook opening 438 and rotation of the first HCFC panel assembly 416 up and away from the second HCFC panel assembly 418.

As used herein, an HCFC clip assembly 430, and an HCFC hook 436 are deemed to “correspond” to each other when an insertion of a tool into a given HCFC clip access slot 434 202 results in a bending or other movement of a given HCFC hook 436 such that an HCFC clip assembly 430 otherwise secured by the given HCFC hook 436 is no longer retained thereby. or at least one implementation, an HCFC clip top 432 may be chamfered in one or more directions in order to facilitate engagement (and disengagement) of a given HCFC clip assembly 430 and a respectively corresponding HCFC hook opening 438.

For at least one implementation, an HCFC clip access slot 434 may align with a HCFC hook 436 such that when a given HCFC hook 436 and a given HCFC clip assembly 430 are coupled with each other (and thereby securing at least a portion of a first HCFC panel assembly 416 to the second HCFC panel assembly 418), a given HCFC hook bottom portion 437 penetrates into at least a portion of the corresponding HCFC clip access slot 434 so as to prevent entry of undesired substances into the HCFC enclosure 400 when the HCFC enclosure 400 is in a secured/closed (as opposed to unsecured/opened) configuration. For at least one implementation, the penetration of a given HCFC hook bottom portion 437 seals the HCFC enclosure 400 so as to prevent intrusion of pollutants into the interior of the HCFC enclosure 400, via the given HCFC clip access slot 434. For at least one implementation, the pollutant may be one or more of a fluid, air, dust, user's fingers, foreign objects, or other items that absent the seal would expose the interior of the HCFC enclosure 400 to penetration by foreign objects.

As shown in FIGS. 4B-4D and for at least one implementation, an HCFC enclosure 400 may include, as one or more first fasteners, one or more pegs (not shown) that correspond with one or more peg holes 440, a second fastener. For example, the HCFC bottom panel 414 may include one or more peg hole 440 into each of which a corresponding peg (not shown) may be inserted. The use of one or more peg holes 440 and corresponding pegs may facilitate alignment of the first HCFC panel assembly 416 with the second HCFC panel assembly 418 while the HCFC enclosure 400 is in a secured/closed configuration.

A method for securing an HCFC enclosure 400 may include a first operation of aligning a first HCFC panel assembly 416, having one or more HCFC hinge clips 424(m) relative to a second HCFC panel assembly 418, having a corresponding number of HCFC hinges 420, with each HCFC hinge 420 including an HCFC hinge shaft 422. A second operation may include rotating the first HCFC panel assembly 416 relative to the second HCFC panel assembly 418, while optionally applying a corresponding pressure therebetween, such that each of the one or more HCFC hinge clips 424(m) envelope and couple with respectively corresponding HCFC hinge shafts 422(m). A third operation may include further rotating the first HCFC panel assembly 416 relative to the second HCFC panel assembly 418 until each of one or more HCFC hooks 436(m) on the first HCFC panel assembly 416 engage with respectively corresponding one or more HCFC clip assemblies 430(m) until the HCFC hook bottom portions 437(m) of the one or more HCFC hooks 436(m) penetrates and seals a respectively corresponding HCFC clip access slot 434(m) for each of one or more HCFC clip assemblies 430(m).

A method for releasing a secured HCFC enclosure 400 may include aligning the secured HCFC enclosure 400 in a tool configured to include one or more prongs, which can be inserted into respectively corresponding HCFC clip access slots 434. A second operation may include applying a pressure, by the prongs, upon each of the HCFC hook bottom portions 437 so as to dislodge each of the corresponding HCFC hooks 436 from the respectively corresponding HCFC clip assemblies 430. A third operation may include rotating the first HCFC panel assembly 416 away from the second HCFC panel assembly 418. The third operation may be performed in conjunction with the second operation or separate from the second operation. A fourth operation may include decoupling the HCFC hinge clips 424 from the respectively corresponding HCFC hinges 420.

It is to be appreciated that an HCFC enclosure 400 provides various advantages over prior art implementations including no visible opening for engagement, by a user, with a HCFC hook 436, via an HCFC front panel 412, an HCFC first side panel 408, an HCFC second side panel 410, or an HCFC back panel 406. Further, the HCFC enclosure 400 provides an enclosure where engagement openings, such as those provided by the HCFC clip access slots 434 are covered by corresponding HCFC hook bottom portions 437 and thereby sealed so as to prevent intrusion of pollutants into the interior of the HCFC enclosure 400. Another advantage is the locating of the HCFC clip assemblies 430 and HCFC hooks 436 along an interior perimeter for an HCFC enclosure 400 increases the structural integrity of the HCFC enclosure 400. Another advantage is the HCFC hinge clips 424 may be configured to facilitate coupling thereof with a respectively corresponding HCFC hinge shaft 422 at a given angle of rotation of the first HCFC panel assembly 416 relative to a horizontal plane formed by the HCFC bottom panel 414 for the second HCFC panel assembly 418. For at least one implementation, such given angle of rotation is between sixty degrees (60 deg.) and ninety degrees (90 deg.). As the first HCFC panel assembly 416 is rotated downwards (towards the “bottom” for the coordinate system used in FIGS. 4A-4D), the HCFC hinge clips 424 lock about the respectively corresponding HCFC hinge shafts 422 and thereby couples the first HCFC panel assembly 416 to the second HCFC panel assembly 418.

Although various implementations have been described above with a certain degree of particularity, or with reference to one or more individual implementations, those skilled in the art could make alterations to the disclosed implementations without departing from the spirit or scope of the present disclosure. The use of the terms “approximately” or “substantially” means that a value of an element has a parameter that is expected to be close to a stated value or position. As is well known in the art, there may be minor variations that prevent the values from being exactly as stated. Accordingly, anticipated variances, such as 10% differences, are reasonable variances that a person having ordinary skill in the art would expect and know are acceptable relative to a stated or ideal goal for one or more implementations of the present disclosure. It is also to be appreciated that the terms “top” and “bottom,” “left” and “right,” “up” or “down,” “first,” “second,” “next,” “last,” “before,” “after,” and other similar terms are used for description and ease of reference purposes and are not intended to be limiting to any orientation or configuration of any elements or sequences of operations for the various implementations of the present disclosure. Further, the terms “coupled,” “connected” or otherwise are not intended to limit such interactions and communication of signals between two or more devices, systems, components or otherwise to direct interactions; indirect couplings and connections may also occur. Further, the terms “and” and “or” are not intended to be used in a limiting or expansive nature and cover any possible range of combinations of elements and operations of an implementation of the present disclosure. Other implementations are therefore contemplated. It is intended that matter contained in the above description and shown in the accompanying drawings shall be interpreted as illustrative of implementations and not limiting. Changes in detail or structure may be made without departing from the basic elements of the present disclosure as described in the following claims.

What is claimed is:

1. An electronic device enclosure comprising:
a first panel assembly;
a second panel assembly;
a plurality of first fasteners; and
a plurality of second fasteners;
wherein a first fastener of the plurality of first fasteners is provided with one of the first panel assembly and the second panel assembly;
wherein a second fastener of the plurality of second fasteners corresponds to the first fastener and is provided with another of the first panel assembly and the second panel assembly;
wherein the first fastener is couplable with the second fastener;
wherein a location inside the electronic device enclosure for at least one of the first fastener and the second fastener is obscured by the first panel assembly and the second panel assembly; and
wherein a coupling of the first fastener with the second fastener results in the electronic device enclosure having a secured configuration.

2. The electronic device enclosure of claim 1,
wherein the electronic device enclosure is a cover flex window (“CFW”) enclosure.

3. The electronic device enclosure of claim 2,
wherein the first fastener is a CFW clip stop assembly; and
wherein the second fastener is a CFW clip assembly.

4. The electronic device enclosure of claim 3,
wherein the CFW clip assembly comprises:
a CFW clip bottom portion formed on a bottom panel of the second panel assembly; and
a CFW clip top portion formed with the CFW clip bottom portion; and
a CFW clip ridge formed as a part of the CFW clip top portion;
wherein the CFW clip top portion extends horizontally relative to the bottom panel of the second panel assembly and above the CFW clip bottom portion;
wherein the CFW clip stop assembly comprises:
a CFW clip stop ridge;
wherein the CFW clip stop ridge is horizontal with a top panel of the first panel assembly; and
a CFW clip stop wall formed with and perpendicular to the CFW clip stop ridge; and
wherein the CFW clip ridge couples with the CFW clip stop ridge when the first panel assembly is coupled with the second panel assembly.

5. The electronic device enclosure of claim 4, further comprising:
a first CFW window;
a second CFW window;
a second-first fastener of the plurality of first fasteners; and
a second-second fastener of the plurality of second fasteners;
wherein the first fastener is provided with the bottom panel for the second panel assembly;
wherein the second-first fastener is provided with the bottom panel for the second panel assembly;
wherein the second fastener is provided with a first side panel for the first panel assembly;
wherein the second-second fastener is provided with a second side panel for the first panel assembly;
wherein the first CFW window corresponds with a first location on the first side panel for the first panel assembly;
wherein the second CFW window corresponds with a second location on the second side panel for the first panel assembly;
wherein the first location and the second location are opposingly aligned;
wherein, when the electronic device enclosure is in the secured configuration, the second-first fastener is coupled with the second-second fastener;
wherein the first CFW window facilitates application of a first force on the first fastener when coupled to the second fastener;
wherein the second CFW window facilitates application of a second force on the second-first fastener when coupled to the second-second fastener; and
wherein upon application of the first force in conjunction with the application of the second force:
the first fastener is released from the second fastener; and
the second-first fastener is released from the second-second fastener; and
the first panel assembly is unsecured from the second panel assembly.

6. The electronic device enclosure of claim 4,
wherein when the first fastener is coupled with the second fastener, the CFW clip bottom portion couples with the CFW clip stop wall to form a rigid combined structure which increases structural rigidity of the electronic device enclosure.

7. The electronic device enclosure of claim 1,
wherein the electronic device enclosure is a cover flex clip (“CFC”) enclosure.

8. The electronic device enclosure of claim 7,
wherein the first fastener is a CFC clip assembly; and
wherein the second fastener is a CFC hook assembly.

9. The electronic device enclosure of claim 8,
wherein the CFC clip assembly comprises:
a CFC clip bottom portion formed on an interior portion of a bottom panel of the second panel assembly;
a CFC clip top portion formed with the CFC clip bottom portion;
wherein the CFC clip top portion extends horizontally relative to the bottom panel of the second panel assembly and above the CFC clip bottom portion; and
a CFC clip ridge formed as a part of the CFC clip top portion;
wherein the CFC hook assembly comprises:
a CFC hook opening; and
a CFW hook bottom portion, located below the CFC hook opening; and
wherein the CFC hook opening is couplable with the CFC clip ridge when the first panel assembly is coupled with the second panel assembly.

10. The electronic device enclosure of claim 9, further comprising:
a CFC clip access slot formed in the bottom panel; and
wherein the CFC clip access slot facilitates access by a tool prong, located below the bottom panel of the electronic device enclosure, into an internal environment formed by a secured electronic device in order to facilitate a release of the CFC clip ridge from the CFC hook opening;
wherein upon releasing of CFC clip ridges for the plurality of first fasteners from corresponding CFC hook openings for the plurality of second fasteners, the first panel assembly is released from the second panel assembly and the electronic device enclosure obtains an unsecured configuration.

11. The electronic device enclosure of claim 7, further comprising:
at least one second-first fastener of the plurality of first fasteners; and
at least one second-second fastener of the plurality of second fasteners;
wherein the at least one second-first fastener is formed on an interior surface of a top panel of the first panel assembly;
wherein the at least one second-second fastener is formed on an interior surface of a back panel of the second panel assembly;
wherein the at least one second-first fastener is couplable with the at least one second-second fastener;
wherein the at least one second-first fastener is a CFC clip assembly; and
wherein the at least one second-second fastener is a CFC access and retention slot.

12. The electronic device enclosure of claim 11,
wherein the CFC clip assembly comprises:
a CFC clip bottom portion formed on the interior surface of the top panel;
a CFC clip top portion formed with the CFC clip bottom portion; and
a CFC clip ridge formed as a part of the CFC clip top portion;
wherein the CFC clip top portion extends horizontally downwards relative to the CFC clip bottom portion;
wherein the CFC access and retention slot comprises an opening for receiving and retaining the CFC clip ridge when the first panel assembly is mated to the second panel assembly;
wherein the CFC access and retention slot receives a prong of a tool which when inserted therein facilitates dislocation of the CFC clip ridge from the CFC access and retention slot; and
wherein upon releasing of CFC clip ridges for the at least one second-first fasteners from corresponding CFC access and retention slots for the second-second fasteners and releasing of any first fastener from any corresponding second fasteners, the first panel assembly is released from the second panel assembly and the electronic device enclosure obtains an unsecured configuration.

13. The electronic device enclosure of claim 1,
wherein the electronic device enclosure is a cover slide & hook clip (“CSHC”) enclosure.

14. The electronic device enclosure of claim 13,
wherein the first fastener is one or more CSHC prong holes;
wherein the second fastener is one or more CSHC prongs;
wherein the one or more CSHC prongs is couplable with a respectively corresponding CSHC prong hole from the one or more CSHC prong holes; and
wherein the electronic device enclosure is in a secured configuration when the one or more CSHC prongs are respectively coupled with the respectively corresponding CSHC prong hole.

15. The electronic device enclosure of claim 13,
wherein the first fastener is one or more CSHC hook assemblies;
wherein the second fastener is one or more CSHC hook cavity assemblies;
wherein the one or more CSHC hook assemblies is couplable with a respectively corresponding CSHC hook cavity assembly from the one or more CSHC hook cavity assemblies; and
wherein the electronic device enclosure is in a secured configuration when the one or more CSHC hook assemblies are respectively coupled with the respectively corresponding CSHC hook cavity assembly.

16. The electronic device enclosure of claim 15, further comprising:
a second-first fastener; and
a second-second fastener;
wherein the second-first fastener is one or more CSHC prong holes;
wherein the second-second fastener is one or more CSHC prongs;
wherein the one or more CSHC prongs is couplable with a respectively corresponding CSHC prong hole from the one or more CSHC prong holes; and
wherein the electronic device enclosure is in a secured configuration when the one or more CSHC prongs are coupled with a respectively corresponding CSHC prong hole and the one or more CSHC hook assemblies are coupled with the respectively corresponding CSHC hook cavity assembly.

17. The electronic device enclosure of claim 1,
wherein the electronic device is a hinged cover with flex clip (“HCFC”) enclosure.

18. The electronic device enclosure of claim 17,
wherein the first fastener is one or more HCFC hinges;
wherein the second fastener is one or more HCFC hinge clips;
wherein the one or more HCFC hinges is couplable with a respectively corresponding HCFC hinge clip; and
wherein the electronic device enclosure is configured into a secured configuration when the one or more HCFC hinges are coupled with the respectively corresponding one or more HCFC hinge clips.

19. The electronic device enclosure of claim 18, further comprising:
a second-first fastener; and
a second-second fastener;
wherein the second-first fastener is one or more HCFC clip assemblies;
wherein the second-second fastener is one or more HCFC hooks;
wherein the one or more HCFC clip assemblies is couplable with a respectively corresponding HCFC hook from the one or more HCFC hooks; and
wherein the electronic device enclosure is in a secured configuration when the one or more HCFC clip assemblies are coupled with a respectively corresponding HCFC hook.

20. The electronic device enclosure of claim 19, further comprising:
a first HCFC panel assembly comprising:
an HCFC top panel;
an HCFC first side panel;
an HCFC second side panel; and
an HCFC front panel;
a second HCFC panel assembly comprising:
an HCFC back panel; and
an HCFC bottom panel;
wherein the one or more HCFC hinges are provided on the HCFC back panel;
wherein the one more HCFC hinge clips are provided on the HCFC top panel;
wherein the one or more HCFC clip assemblies are provided on the HCFC bottom panel;
wherein the one or more HCFC hooks are provided on at least one of the HCFC top panel, the HCFC first side panel, the HCFC front panel, and the HCFC second side panel.
